(19) United States
(12) Patent Application Publication
(10) Pub. No.: US 2024/0371730 A1
(43) Pub. Date: Nov. 7, 2024

(54) SEMICONDUCTOR DEVICE AND SEMICONDUCTOR PACKAGE INCLUDING THE SAME

(71) Applicant: Samsung Electronics Co., Ltd., Suwon-si (KR)

(72) Inventors: Ahreum Lee, Suwon-si (KR); Woosung Yang, Suwon-si (KR); Jimo Gu, Suwon-si (KR); Sukkang Sung, Suwon-si (KR)

(21) Appl. No.: 18/411,171

(22) Filed: Jan. 12, 2024

(30) Foreign Application Priority Data
May 4, 2023 (KR) 10-2023-0058080

(51) Int. Cl. H01L 23/48; H01L 23/00; H01L 25/065; H10B 80/00

(52) U.S. Cl. CPC H01L 23/481; H01L 21/76898; H01L 24/08; H01L 24/16; H01L 25/0657; H01L 25/18; H10B 80/00; H01L 2224/08145; H01L 2224/16145; H01L 2224/16227; H01L 2225/06513; H01L 2225/06541; H01L 2225/06562

(57) ABSTRACT

Disclosed are semiconductor devices and semiconductor packages including the same. The semiconductor package includes a package substrate, and a first chip stack and a second chip stack that are stacked on the package substrate. Each of the first and second chip stacks includes a plurality of vertically stacked semiconductor chips. Each of the semiconductor chips includes a plurality of first vertical connection structures and a plurality of second vertical connection structures. The first vertical connection structures of the semiconductor chips in the second chip stack overlap and are connected with the second vertical connection structures of the semiconductor chips in the first chip stack.

### CROSS-REFERENCE TO RELATED APPLICATION

This U.S. nonprovisional application claims priority under 35 U.S.C § 119 to Korean Patent Application No. 10-2023-0058080 filed on May 4, 2023 in the Korean Intellectual Property Office, the disclosure of which is hereby incorporated by reference in its entirety.

### BACKGROUND

The present inventive concepts relate to a semiconductor device and a semiconductor package including the same.

A semiconductor device capable of storing a large amount of data in an electronic system may be desirable. Therefore, studies have been conducted to increase data storage capacity of semiconductor devices. For example, a semiconductor device including three-dimensionally arranged memory cells, instead of two-dimensionally arranged memory cells, has been suggested.

### SUMMARY

Some embodiments of the present inventive concepts provide a semiconductor device with improved reliability and increased integration.

Some embodiments of the present inventive concepts provide a semiconductor package including a plurality of semiconductor devices.

The object of the present inventive concepts is not limited to the mentioned above, and other objects which have not been mentioned above will be clearly understood to those skilled in the art from the following description.

According to some embodiments of the present inventive concepts, a semiconductor package may include a package substrate; and a first chip stack and a second chip stack that are stacked on the package substrate. Each of the first and second chip stacks may include a plurality of vertically stacked semiconductor chips. Each of the semiconductor chips may include a plurality of first vertical connection structures and a plurality of second vertical connection structures. The first vertical connection structures of the semiconductor chips in the second chip stack may overlap and may be connected (e.g., electrically connected) with the second vertical connection structures of the semiconductor chips in the first chip stack. In some embodiments, the first chip stack may be between the package substrate and the second chip stack.

According to some embodiments of the present inventive concepts, a semiconductor device may include a semiconductor substrate; a peripheral circuit structure that includes peripheral circuits on (e.g., integrated on) the semiconductor substrate and first bonding pads connected (e.g., electrically connected) to the peripheral circuits; a cell array structure that includes second bonding pad contacting (e.g., bonded to) the first bonding pads, wherein the cell array structure includes three-dimensionally integrated memory cells; a plurality of first vertical connection structures electrically connected to the peripheral circuits, wherein each of the first vertical connection structures includes a first upper pad, a first lower pad opposite to the first upper pad, and a first through via that connects (e.g., electrically connects) the first upper pad to the first lower pad; and a plurality of second vertical connection structures insulated from the peripheral circuits, wherein each of the second vertical connection structures includes a second upper pad, a second lower pad opposite to the second upper pad, and a second through via that connects (e.g., electrically connects) the second upper pad to the second lower pad. The first and second upper pads may be on an uppermost surface of the cell array structure. The first and second lower pads may be on a lowermost surface of the peripheral circuit structure.

According to some embodiments of the present inventive concepts, a semiconductor package may include a package substrate; a first chip stack on the package substrate; a second chip stack on the first chip stack; and a buffer chip on the package substrate. Each of the first and second chip stacks may include a plurality of vertically stacked semiconductor chips. Each of the semiconductor chips may include: a semiconductor substrate; a peripheral circuit structure that includes peripheral circuits integrated on the semiconductor substrate and first bonding pads connected (e.g., electrically connected) to the peripheral circuits; a cell array structure that includes second bonding pad contacting (e.g., bonded to) the first bonding pads, wherein the cell array structure includes three-dimensionally integrated memory cells; a plurality of first vertical connection structures electrically connected to the peripheral circuits; and a plurality of second vertical connection structures insulated from (e.g., electrically insulated from) the peripheral circuits. The first vertical connection structures of the semiconductor chips in the second chip stack may overlap and may be connect (e.g., electrically connected) with the second vertical connection structures of the semiconductor chips in the first chip stack. The first vertical connection structures of the second chip stack may be connected (e.g., electrically connected) to the buffer chip through the second vertical connection structures of the first chip stack.

Details of examples embodiments are provided in the description and drawings.

### BRIEF DESCRIPTION OF DRAWINGS

FIG. 1 illustrates a simplified schematic diagram showing an electronic system that includes a semiconductor device according to some embodiments of the present inventive concepts.

FIG. 2 illustrates a simplified perspective view showing an electronic system that includes a semiconductor device according to some embodiments of the present inventive concepts.

FIG. 3A illustrates a simplified cross-sectional view showing a semiconductor package according to some embodiments of the present inventive concepts.

FIG. 3B illustrates an enlarged view showing the section P1 of FIG. 3A.

FIG. 4A illustrates a simplified cross-sectional view showing a semiconductor package according to some embodiments of the present inventive concepts.

FIG. 4B illustrates an enlarged view showing the section P2 of FIG. 4A.

FIG. 5A illustrates a simplified plan view showing a semiconductor chip according to some embodiments of the present inventive concepts.

FIG. 5B illustrates a simplified plan view showing a semiconductor package including the semiconductor chip depicted in FIG. 5A.

FIG. 6A illustrates a simplified plan view showing a semiconductor chip according to some embodiments of the present inventive concepts.

FIG. 6B illustrates a simplified plan view showing a semiconductor package including the semiconductor chip depicted in FIG. 6A.

FIG. 7A illustrates a simplified plan view showing a semiconductor chip according to some embodiments of the present inventive concepts.

FIG. 7B illustrates a simplified plan view showing a semiconductor package including the semiconductor chip depicted in FIG. 7A.

FIG. 8 illustrates a simplified cross-sectional view showing a semiconductor package according to some embodiments of the present inventive concepts.

FIG. 9A illustrates a simplified plan view showing a semiconductor chip according to some embodiments of the present inventive concepts.

FIG. 9B illustrates a simplified plan view showing a semiconductor package including the semiconductor chip depicted in FIG. 9A.

FIG. 10A illustrates a cross-sectional view showing a semiconductor chip according to some embodiments of the present inventive concepts.

FIG. 10B illustrates an enlarged view showing the section P3 of FIG. 10A.

FIG. 11 illustrates a cross-sectional view showing a semiconductor chip according to some embodiments of the present inventive concepts.

FIGS. 12 to 20 illustrate cross-sectional views showing a method of fabricating a semiconductor chip according to some embodiments of the present inventive concepts.

### DETAILED DESCRIPTION

With reference to the accompanying drawings, the following will now describe in detail a semiconductor device and a semiconductor package including the same according to some embodiments of the present inventive concepts.

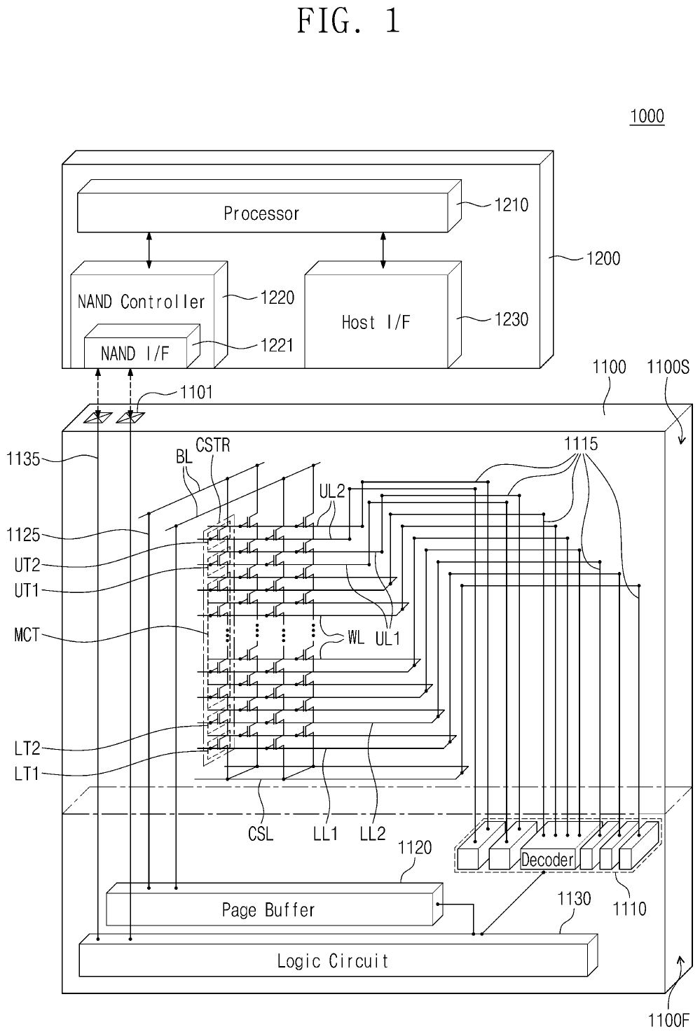

FIG. 1 illustrates a simplified schematic diagram showing an electronic system that includes a semiconductor device according to some embodiments of the present inventive concepts.

Referring to FIG. 1, an electronic system 1000 according to some embodiments of the present inventive concepts may include a semiconductor device 1100 and a controller 1200 electrically connected to the semiconductor device 1100. The electronic system 1000 may be a storage device that includes a single or a plurality of semiconductor devices 1100, or may be an electronic device that includes the storage device. For example, the electronic system 1000 may be a solid state drive (SSD) device, a universal serial bus (USB), a computing system, a medical apparatus, or a communication apparatus, each of which includes a single or a plurality of semiconductor devices 1100.

The semiconductor device 1100 may be a nonvolatile memory device, such as a NAND Flash memory device. The semiconductor device 1100 may include a first structure 1100F and a second structure 1100S on the first structure 1100F. In some embodiments, the first structure 1100F may be disposed on a side of the second structure 1100S.

The first structure 1100F may be a peripheral circuit structure that includes a decoder circuit 1110, a page buffer 1120, and a logic circuit 1130. The second structure 1100S may be a memory cell structure that includes bit lines BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and memory cell transistors MCT disposed between the lower transistors LT1 and LT2 and the upper transistors UT1 and UT2. The number of the lower transistors LT1 and LT2 and of the upper transistors UT1 and UT2 may be variously changed in accordance with embodiments.

In some embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In some embodiments, the lower transistors LT1 and LT2 may include a lower erase control transistor LT1 and a ground selection transistor LT2 that are connected in series. The upper transistors UT1 and UT2 may include a string selection transistor UT1 and an upper erase control transistor UT2 that are connected in series. One or both of the lower and upper erase control transistors LT1 and UT1 may be employed to perform an erase operation in which a gate induced drain leakage (GIDL) phenomenon is used to erase data stored in the memory cell transistors MCT.

The common source line CSL, the first and second gate lower lines LL1 and LL2, the word lines WL, and the first and second gate upper lines UL1 and UL2 may be electrically connected to the decoder circuit 1110 through first connection lines 1115 that extend from the first structure 1100F toward the second structure 1100S. The bit lines BL may be electrically connected to the page buffer 1120 through second connection lines 1125 that extend from the first structure 1100F toward the second structure 1100S.

In the first structure 1100F, the decoder circuit 1110 and the page buffer 1120 may perform a control operation to at least one selection memory cell transistor among the plurality of memory cell transistors MCT. The logic circuit 1130 may control the decoder circuit 1110 and the page buffer 1120. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135 that extends from the first structure 1100F toward the second structure 1100S.

Although not shown, the first structure 1100F may include a voltage generator. The voltage generator may produce program voltages, read voltages, pass voltages, and verification voltages that are required for operating the memory cell strings CSTR. The program voltage may be relatively higher (e.g., about 20 V to about 40 V) than the read voltage, the pass voltage, and the verification voltage.

In some embodiments, the first structure 1100F may include high-voltage transistors and low-voltage transistors. The decoder circuit 1110 may include pass transistors connected to the word lines WL of the memory cell strings CSTR. The pass transistors may include high-voltage transistors capable of withstanding high voltages such as program voltages applied to the word lines WL in a program operation. The page buffer 1120 may also include high-voltage transistors capable of withstanding high voltages.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 that includes the controller 1200. The processor 1210 may operate based on predetermined firmware, and may control the NAND controller 1220 to access the semiconductor device 1100. The NAND controller 1220 may include a NAND interface 1221 that processes communication with the semiconductor device 1100. The NAND interface 1221 may be used to transfer therethrough a control command to control the semiconductor device 1100, data intended to be written on the memory cell transistors MCT of the semiconductor device 1100, and/or data intended to be read from the memory cell transistors MCT of the semiconductor device 1100. The host interface 1230 may provide the electronic system 1000 with communication with an external host. When a control command is received through the host interface 1230 from an external host, the semiconductor device 1100 may be controlled by the processor 1210 in response to the control command.

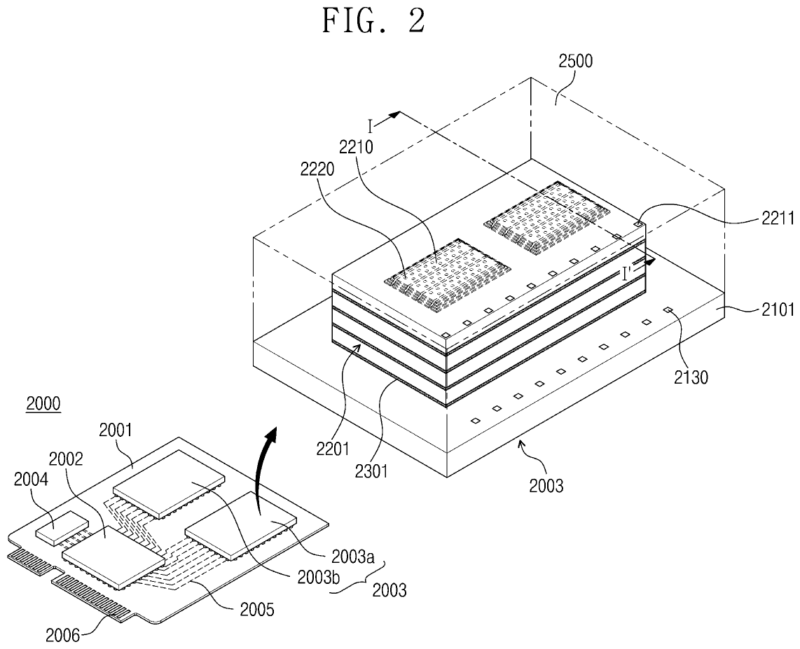

FIG. 2 illustrates a simplified perspective view showing an electronic system that includes a semiconductor device according to some embodiments of the present inventive concepts.

Referring to FIG. 2, an electronic system 2000 according to some embodiments of the present inventive concepts may include a main board 2001, and may also include a controller 2002, at least one semiconductor package 2003, and a dynamic random access memory (DRAM) 2004 that are mounted on the main board 2001. The semiconductor package 2003 and the DRAM 2004 may be connected to the controller 2002 through wiring patterns 2005 formed on the main board 2001.

The main board 2001 may include a connector 2006 including a plurality of pins that are coupled to an external host. The number and arrangement of the plurality of pins in the connector 2006 may be changed based on a communication interface between the electronic system 2000 and the external host. In some embodiments, the electronic system 2000 may communicate with the external host through one or more interfaces, for example, universal serial bus (USB), peripheral component interconnect express (PIC-Express), serial advanced technology attachment (SATA), and M-PHY for universal flash storage (UFS). In some embodiments, the electronic system 2000 may operate with power supplied through the connector 2006 from the external host. The electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but also a DRAM controller for controlling the DRAM 2004.

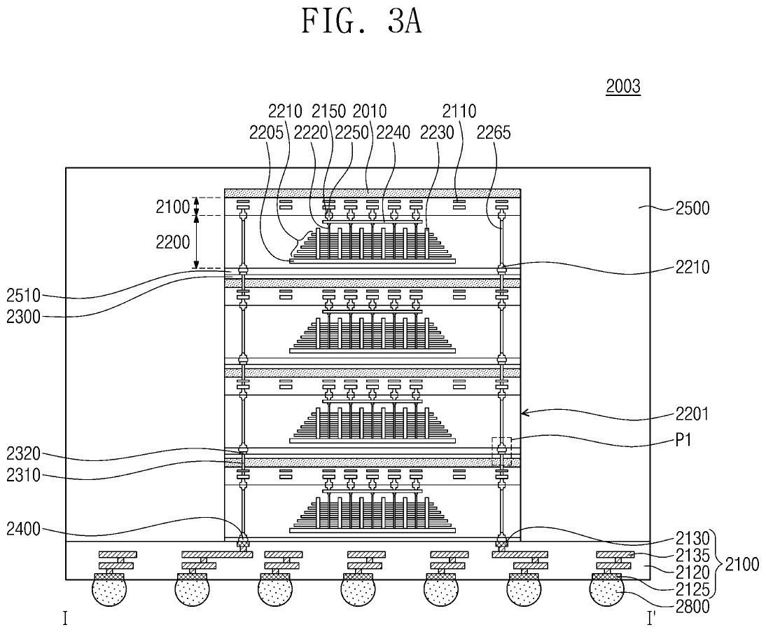

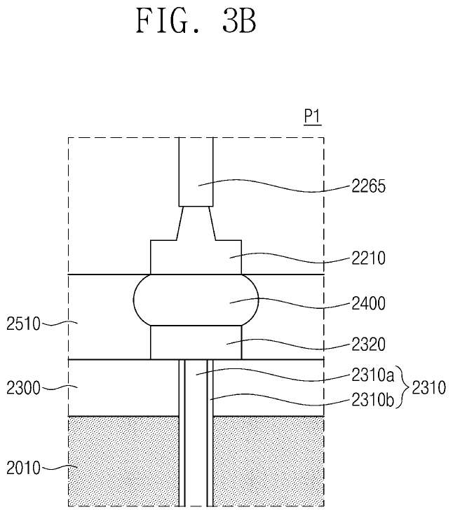

The semiconductor package 2003 may include first and second semiconductor packages 2003a and 2003b that are spaced apart from each other. Each of the first and second semiconductor packages 2003a and 2003b may include a plurality of semiconductor chips 2201. Each of the first and second semiconductor packages 2003a and 2003b may include a package substrate 2101, semiconductor chips 2201 on the package substrate 2101, adhesion layers 2301 disposed on bottom surfaces of the semiconductor chips 2201, connection structures (e.g., connection structures 2400 in FIG. 3A) that electrically connect the semiconductor chips 2201 to the package substrate 2101, and a molding layer 2500 that lies on the package substrate 2101 and covers the semiconductor chips 2201 and the connection structures.

The package substrate 2101 may be a printed circuit board including upper pads 2130. Each of the semiconductor chips 2201 may include one or more input/output pads 2211. The input/output pad 2211 may correspond to the input/output pad 1101 of FIG. 1. Each of the semiconductor chips 2201 may include gate stack structures 2210 and memory channel structures 2220. Each of the semiconductor chips 2201 may include a semiconductor device according to some embodiments of the present inventive concepts which will be discussed below.

In some embodiments, the connection structure (e.g., connection structures 2400 in FIG. 3A) may be a bonding wire that electrically connects the input/output pad 2211 to the upper pad 2130. Therefore, in each of the first and second semiconductor packages 2003a and 2003b, the semiconductor chips 2201 may be electrically connected to each other in a bonding wire manner, and may be electrically connected to the upper pads 2130 of the package substrate 2101. In some embodiments, in each of the first and second semiconductor packages 2003a and 2003b, the semiconductor chips 2201 may be electrically connected to each other through connection structures such as through silicon vias (TSV) instead of the connection structures, such as bonding wires.

In some embodiments, the controller 2002 and the semiconductor chips 2201 may be included in a single package. For example, the controller 2002 and the semiconductor chips 2201 may be mounted on an interposer substrate other than the main board 2001, and may be connected to each other through wiring lines formed on the interposer substrate.

FIG. 3A illustrates a simplified cross-sectional view showing a semiconductor package according to some embodiments of the present inventive concepts. FIG. 3B illustrates an enlarged view showing the section P1 of FIG. 3A.

FIG. 3A depicts an example of the semiconductor package 2003 illustrated in FIG. 2, conceptually showing a cross-section taken along the line I-I′ of the semiconductor package 2003 illustrated in FIG. 2.

Referring to FIGS. 3A and 3B, a printed circuit board may be used as the package substrate (e.g., the package substrate 2101 in FIG. 2) of the semiconductor package 2003. The package substrate may include a package substrate body 2120, upper pads 2130 (see also the upper pads 2130 of FIG. 2) disposed on a top surface of the package substrate body 2120, lower pads 2125 disposed or exposed on a bottom surface of the package substrate body 2120, and internal wiring lines 2135 by which the upper pads 2130 and the lower pads 2125 are electrically connected to each other in the package substrate body 2120. The upper pads 2130 may be electrically connected to the connection structures 2400. The lower pads 2125 may be connected through conductive connectors 2800 to the wiring patterns 2005 of the main board 2001 in the electronic system 2000, as shown in FIG. 2.

Referring to FIG. 3A, the semiconductor chips 2201 may be vertically aligned with each other in the semiconductor package 2003. Each of the semiconductor chips 2201 may include a semiconductor substrate 2010, a first structure 2100 formed below the semiconductor substrate 2010, and a second structure 2200 disposed below and wafer-bonded to the first structure 2100. In some embodiments, the first structure 2100 may be between the semiconductor substrate 2010 and the second structure 2200, as illustrated in FIG. 3A.

The first structure 2100 may include a peripheral circuit region including peripheral wiring lines 2110 and first bonding structures 2150. The second structure 2200 may include a common source line 2205, a gate stack structure 2210 between the common source line 2205 and the first structure 2100, memory channel structures 2220 and separation structures 2230 that penetrate the gate stack structure 2210, and second bonding structures 2250 electrically connected to the memory channel structures 2220 and word lines (see word lines WL of FIG. 1) of the gate stack structure 2210. For example, the second bonding structures 2250 may be electrically connected to the memory channel structures 2220 and the word lines (see word lines WL of FIG. 1) through bit lines 2240 electrically connected to the memory channel structures 2220 and through gate connection lines electrically connected to the word lines (see word lines WL of FIG. 1). The first bonding structures 2150 of the first structure 2100 and the second bonding structures 2250 of the second structure 2200 may be bonded to each other while being in contact with each other. The first and second bonding structures 2150 and 2250 may have their bonding portions formed of, for example, copper (Cu). As used herein “an element A penetrates an element B” (or similar language) may mean that at least a portion of the element A extends into the element B such that the at least a portion of the element A is in the element B.

The semiconductor chips 2201 other than an uppermost one of the semiconductor chips 2201 may include a backside dielectric layer 2300, backside input/output pads 2320 on the backside dielectric layer 2300, and through electrode structures 2310 that penetrate the semiconductor substrate 2010 and the backside dielectric layer 2300 and electrically connect the peripheral wiring lines 2110 of the first structure 2100 to the backside input/output pads 2320. Each of the through electrode structures 2310 may include a through electrode 2310a and a dielectric spacer 2310b that surrounds a lateral surface of the through electrode 2310a.

The semiconductor package 2003 may further include connection structures 2400, such as conductive bumps, disposed on a lower portion of each of the semiconductor chips 2201. The connection structures 2400 may electrically connect the semiconductor chips 2201 to each other, and may also electrically connect the semiconductor chips 2201 to the package substrate (e.g., the package substrate 2101 in FIG. 2). An underfill material layer 2510 may surround a lateral surface of the connection structure 2400.

The first structure 2100 of FIG. 3A may correspond to a peripheral circuit structure in the following embodiments, and the second structure 2200 of FIG. 3A may correspond to a cell array structure in the following embodiments.

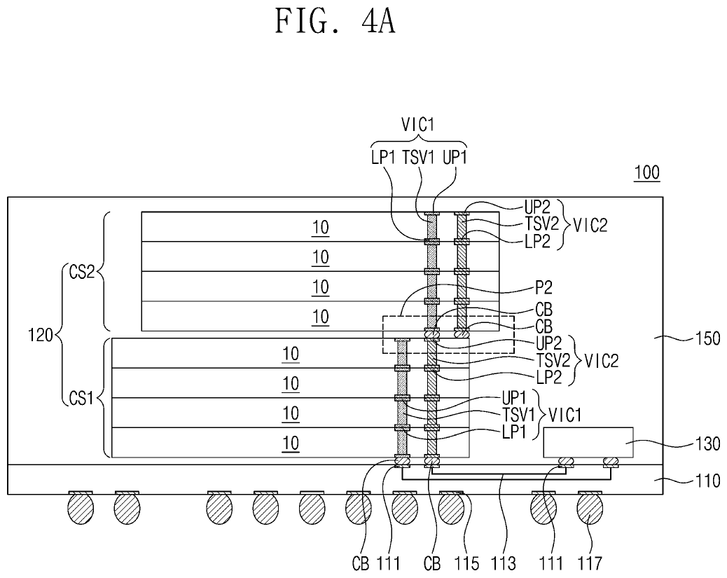

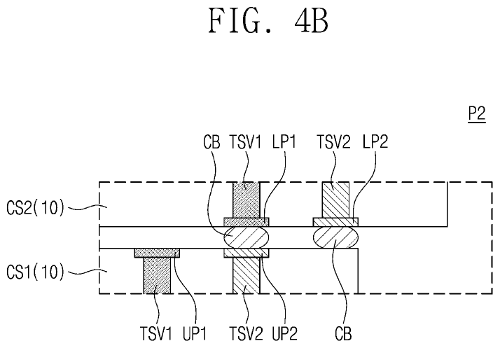

FIG. 4A illustrates a simplified cross-sectional view showing a semiconductor package according to some embodiments of the present inventive concepts. FIG. 4B illustrates an enlarged view showing the section P2 of FIG. 4A.

Referring to FIG. 4A, a semiconductor package 100 may include a package substrate 110, a memory device 120, a buffer chip 130, and a molding layer 150.

A printed circuit board (PCB), a flexible substrate, a tape substrate, or any other kind of substrate may be used as the package substrate 110. For example, the package substrate 110 may be a printed circuit board in which internal wiring lines are formed.

The package substrate 110 may have a top surface and a bottom surface that are opposite to each other, and may include upper and lower conductive pads 111 and 115 and internal wiring lines 113. The upper conductive pads 111 may be arranged on the top surface of the package substrate 110, and the lower conductive pads 115 may be arranged on the bottom surface of the package substrate 110. The upper conductive pads 111 may be electrically connected through the internal wiring lines 113 to the lower conductive pads 115. A plurality of external coupling terminals 117 may be attached to the lower conductive pads 115. A ball grid array (BGA) may be provided as the external coupling terminals 117.

The memory device 120 may include a first chip stack CS1 on the package substrate 110 and a second chip stack CS2 on the first chip stack CS1. In some embodiments, the first chip stack CS1 may be between the package substrate 110 and the second chip stack CS2, as illustrated in FIG. 4.

Each of the first and second chip stacks CS1 and CS2 may include a plurality of semiconductor chips 10 (or semiconductor devices) stacked on the package substrate 110. The first chip stack CS1 may include first ones of the plurality of semiconductor chips 10 (also referred to as a plurality of first semiconductor chips), and the second chip stack CS2 may include second ones of the plurality of semiconductor chips 10 (also referred to as a plurality of second semiconductor chips).

For example, each of the first and second chip stacks CS1 and CS2 may include four semiconductor chips 10 that are vertically stacked. Each of the first and second chip stacks CS1 and CS2 may not have any limitation imposed on the stacking number of the semiconductor chips 10, and may have six, eight, sixteen, or any other suitable numbers of semiconductor chips 10. In some embodiments, the stacking number of the semiconductor chips 10 in the first chip stack CS1 may be different from that of the semiconductor chips 10 in the second chip stack CS2.

In each of the first and second chip stacks CS1 and CS2, the semiconductor chips 10 may be stacked to allow their sidewalls to be aligned with each other on the package substrate 110. The semiconductor chips 10 of the second chip stack CS2 may be disposed to have their sidewalls misaligned with those of the semiconductor chips 10 of the first chip stack CS1.

According to some embodiments, each of the semiconductor chips 10 may include first vertical connection structures VIC1 and second vertical connection structures VIC2.

For example, each of the first vertical connection structures VIC1 may include a first upper pad UP1, a first lower pad LP1, and a first through via TSV1 that connects the first upper and lower pads UP1 and LP1 to each other. The first upper pad UP1 may be vertically aligned with and overlap the first lower pad LP1, as illustrated in FIG. 4A. Each of the second vertical connection structures VIC2 may include a second upper pad UP2, a second lower pad LP2, and a second through via TSV2 that connects the second upper and lower pads UP2 and LP2 to each other. The second upper pad UP2 may be vertically aligned with and overlap the second lower pad LP2, as illustrated in FIG. 4A. The first and second vertical connection structures VIC1 and VIC2 may include, for example, at least one selected from doped semiconductors (e.g., doped silicon), metals (e.g., tungsten, copper, or aluminum), conductive metal nitrides (e.g., titanium nitride or tantalum nitride), and transition metals (e.g., titanium or tantalum).

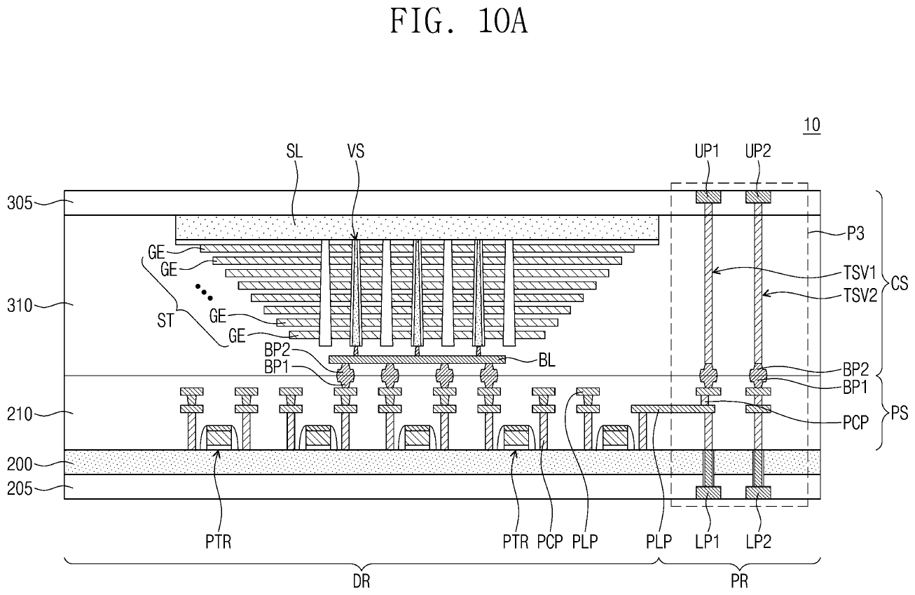

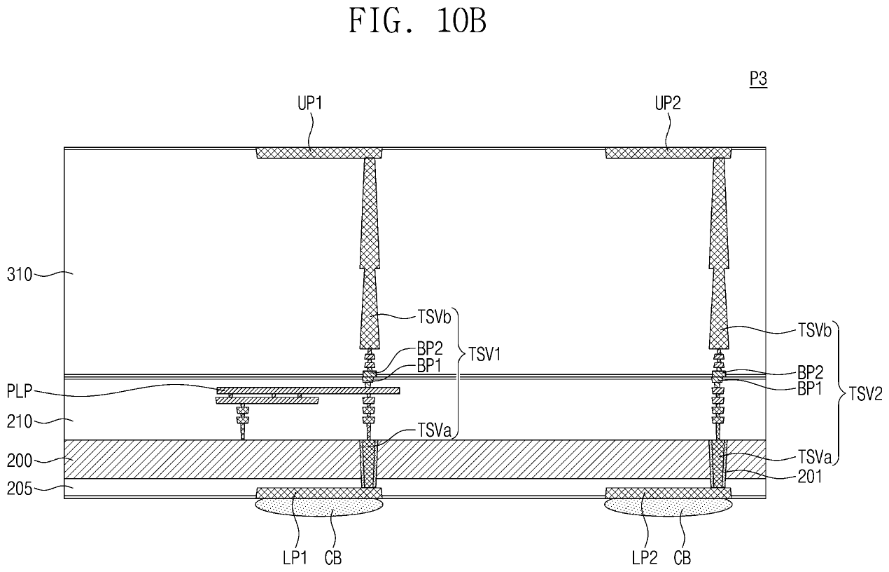

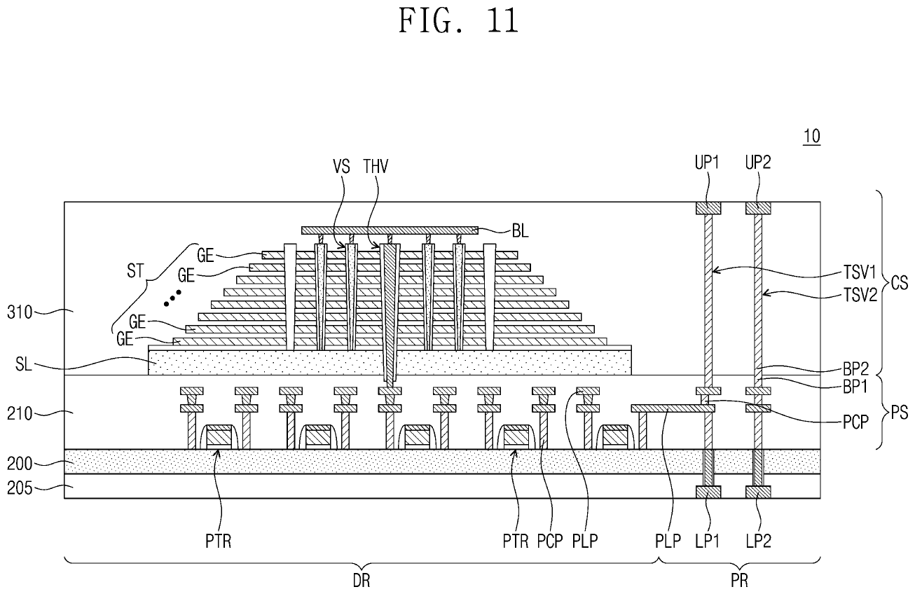

In each of the semiconductor chips 10, the first vertical connection structures VIC1 may be electrically connected to an internal circuit (e.g., conductive elements therein) of a corresponding semiconductor chip 10, and the second vertical connection structures VIC2 may be electrically insulated from the internal circuit. This will be further discussed in detail below with reference to FIGS. 10A, 10B, and 11. Stated differently, each of the first vertical connection structures VIC1 of a single semiconductor chip 10 of the first and second chip stacks CS1 and CS2 may be electrically connected to at least one conductive element (e.g., a source/drain region or a bit line) of that single semiconductor chip 10, and the second vertical connection structures VIC2 of a single semiconductor chip 10 of the first and second chip stacks CS1 and CS2 may not be electrically connected to (i.e., may be electrically insulated from) any conductive element of that single semiconductor chip 10.

In the semiconductor chips 10 (also referred to as a plurality of first semiconductor chips) of the first chip stack CS1, the first and second vertical connection structures VIC1 and VIC2 may be electrically connected through the package substrate 110 to the buffer chip 130.

The first vertical connection structures VIC1 of the semiconductor chips 10 (also referred to as a plurality of second semiconductor chips) in the second chip stack CS2 may overlap and connect with the second vertical connection structures VIC2 of the semiconductor chips 10 in the first chip stack CS1. For example, the second vertical connection structures VIC2 of the semiconductor chips 10 in the first chip stack CS1 may connect the buffer chip 130 to the first vertical connection structures VIC1 of the semiconductor chips 10 in the second chip stack CS2.

The first chip stack CS1 may be flip-chip mounted on the package substrate 110. An uppermost semiconductor chip 10 of the first chip stack CS1 may be electrically connected through connection bumps CB to the upper conductive pads 111 of the package substrate 110.

In each of the first and second chip stacks CS1 and CS2, the first and second upper pads UP1 and UP2 of the semiconductor chips 10 may be electrically connected through connection bumps (not shown) to the first and second lower pads LP1 and LP2 of the semiconductor chips 10. In some embodiments, in each of the first and second chip stacks CS1 and CS2, the first and second upper pads UP1 and UP2 of the semiconductor chips 10 may be directly bonded and connected to the first and second lower pads LP1 and LP2 of the semiconductor chips 10.

The connection bumps CB may be provided between the first chip stack CS1 and the second chip stack CS2. The connection bumps CB may be in contact with the first and second lower pads LP1 and LP2 of a lowermost semiconductor chip 10 in the second chip stack CS2.

Referring to FIG. 4B, one of the connection bumps CB may be connected between the first lower pad LP1 of the lowermost semiconductor chip 10 in the second chip stack CS2 and the second upper pad UP2 of the uppermost semiconductor chip 10 in the first chip stack CS1.

One of the connection bumps CB may be disposed between the second lower pad LP2 of the lowermost semiconductor chip 10 in the second chip stack CS2 and a dielectric layer of the uppermost semiconductor chip 10 in the first chip stack CS1.

In some embodiments, the second vertical connection structures VIC2 of the second chip stack CS2 may be provided as dummies and may be electrically floated. For example, the second vertical connection structures VIC2 of the second chip stack CS2 may not be electrically connected to any conductive element of the semiconductor chips 10 of the second chip stack CS2.

According to some embodiments, the semiconductor chips 10 may be memory chips in which data are stored. For example, the semiconductor chips 10 may be NAND Flash memory chips, dynamic random access memory (DRAM) chips, static random access memory (SRAM) chips, phase change random access memory (PRAM) chips, resistive random access memory (RRAM) chips, ferromagnetic random access memory (FeRAM) chips, or magnetic random access memory (MRAM) chips.

The buffer chip 130 may be connected between the memory device 120 and a memory controller (not shown). The buffer chip 130 may be electrically connected through the package substrate 110 to the memory device 120.

The buffer chip 130 may branch one channel provided from the memory controller into N numbers (e.g., two, four, or eight) of channels. First and second internal channels may be provided between the buffer chip 130 and the memory device 120, the first chip stack CS1 may be connected through the first internal channel to the buffer chip 130, and the second chip stack CS2 may be connected through the second internal channel to the buffer chip 130.

The buffer chip 130 may be, for example, a frequency boosting interface (FBI) device. The frequency boosting interface (FBI) device may be provided to reduce an effect of capacitance caused by input/output pads of the memory device 120. The reduction in capacitance caused by input/output pads of the memory device 120 may increase in signal delivery speed to the memory device 120.

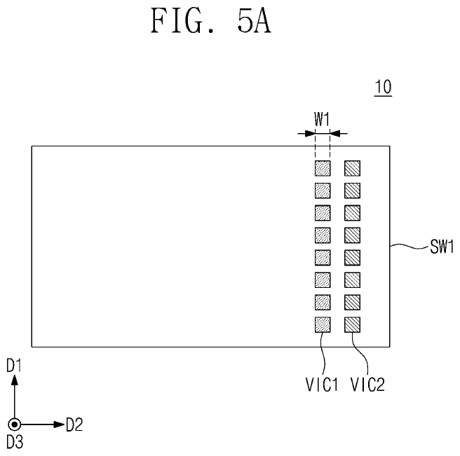

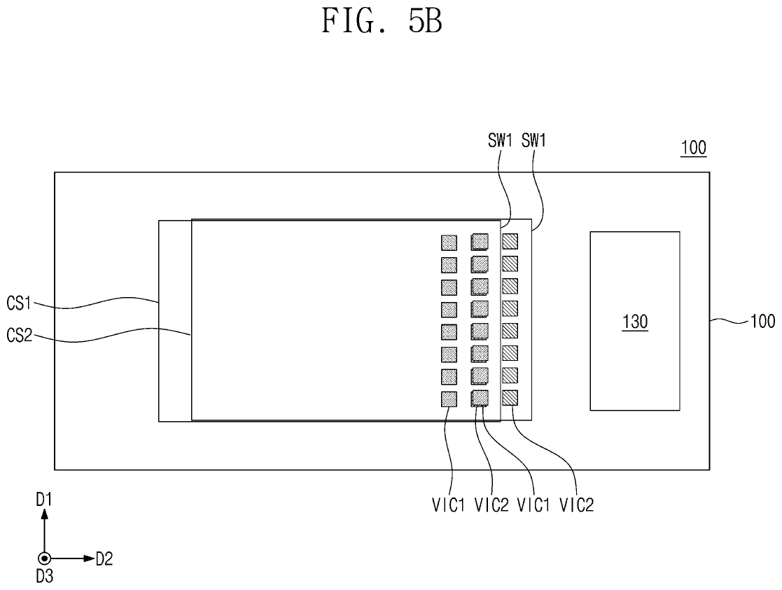

FIG. 5A illustrates a simplified plan view showing a semiconductor chip according to some embodiments of the present inventive concepts. FIG. 5B illustrates a simplified plan view showing a semiconductor package including the semiconductor chip depicted in FIG. 5A. The same technical features as those of the embodiments discussed above may be omitted in the interest of brevity of description.

Referring to FIG. 5A, each semiconductor chip 10 according to some embodiments of the present inventive concepts may have a structure in which the first and second vertical connection structures VIC1 and VIC2 are arranged adjacent or on an edge of the semiconductor chip 10.

For example, each of the semiconductor chips 10 may have a first sidewall SW1 parallel to a first direction D1, and the first vertical connection structures VIC1 may be arranged adjacent to the first sidewall SW1. The first vertical connection structures VIC1 may be arranged at a regular interval along the first direction D1, and each of the first vertical connection structures VIC1 may have a width W1 of about 30 μm to about 50 μm. The width W1 may be a width in the second direction D2.

The second vertical connection structures VIC2 may be arranged spaced apart in a second direction D2 from the first vertical connection structures VIC1. For example, the second vertical connection structures VIC2 may be arranged between the first vertical connection structures VIC1 and the first sidewall SW1 of the semiconductor chip 10.

Referring to FIG. 5B, the first chip stack CS1 and the second chip stack CS2 may be stacked on the package substrate 110, and the first sidewall SW1 of the second chip stack CS2 may be spaced apart in the second direction D2 from the first sidewall SW1 of the first chip stack CS1. When viewed in plan, the first vertical connection structures VIC1 of the second chip stack CS2 may overlap the second vertical connection structures VIC2 of the first chip stack CS1. For example, the first vertical connection structures VIC1 of the second chip stack CS2 may be electrically connected through the buffer chip 130 to the second vertical connection structures VIC2 of the first chip stack CS1. In some embodiments, the first chip stack CS1 may be between the package substrate 110 and the second chip stack CS2.

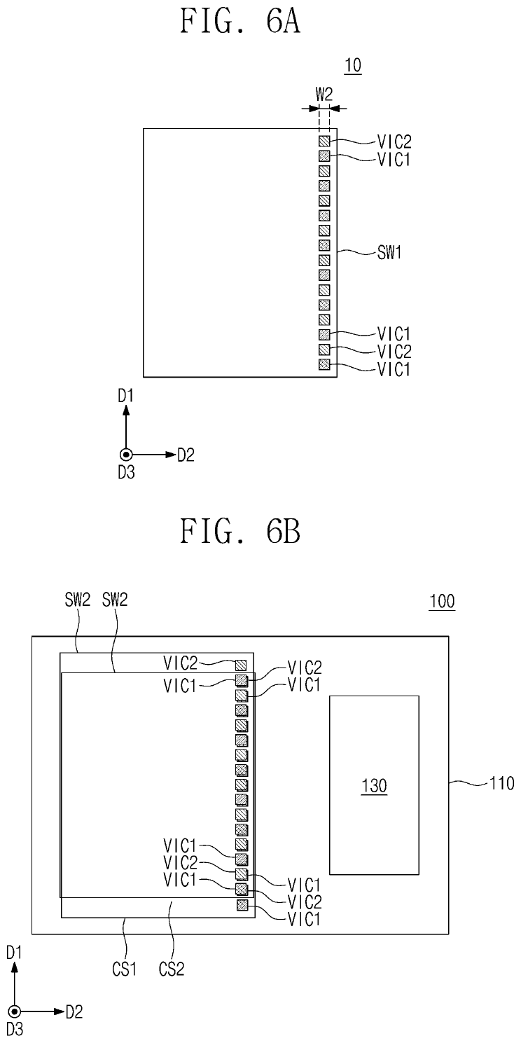

FIG. 6A illustrates a simplified plan view showing a semiconductor chip according to some embodiments of the present inventive concepts. FIG. 6B illustrates a simplified plan view showing a semiconductor package including the semiconductor chip depicted in FIG. 6A. The same technical features as those of the embodiments discussed above may be omitted in the interest of brevity of description.

Referring to FIG. 6A, each semiconductor chip 10 according to some embodiments of the present inventive concepts may have a first sidewall SW1 parallel to the first direction D1 and a second sidewall SW2 parallel to the second direction D2 orthogonal to the first direction D1.

The first and second vertical connection structures VIC1 and VIC2 of each semiconductor chip 10 may be arranged adjacent to the first sidewall SW1 and alternately with each other along the first direction D1. Each of the first and second vertical connection structures VIC1 and VIC2 may have a width W2 of about 30 μm to about 50 μm. The width W2 may be a width in the second direction D2.

Referring to FIG. 6B, the semiconductor package 100 according to some embodiments of the present inventive concepts may include the first and second chip stacks CS1 and CS2 stacked on the package substrate 110.

The first sidewall SW1 of the second chip stack CS2 may be vertically aligned with the first sidewall SW1 of the first chip stack CS1, and the second sidewall SW2 of the second chip stack CS2 may be spaced apart in the first direction D1 from the second sidewall SW2 of the first chip stack CS1.

When viewed in plan, the first vertical connection structures VIC1 of the second chip stack CS2 may overlap the second vertical connection structures VIC2 of the first chip stack CS1. For example, the first vertical connection structures VIC1 of the second chip stack CS2 may be electrically connected to the buffer chip 130 through the second vertical connection structures VIC2 of the first chip stack CS1. In some embodiments, the first chip stack CS1 may be between the package substrate 110 and the second chip stack CS2.

In some embodiments, one of the first vertical connection structures VIC1 of the first chip stack CS1 may not overlap any of the first and second vertical connection structures VIC1 and VIC2 of the second chip stack CS2. In some embodiments, one of the second vertical connection structures VIC2 of the second chip stack CS2 may not overlap any of the first and second vertical connection structures VIC1 and VIC2 of the first chip stack CS1.

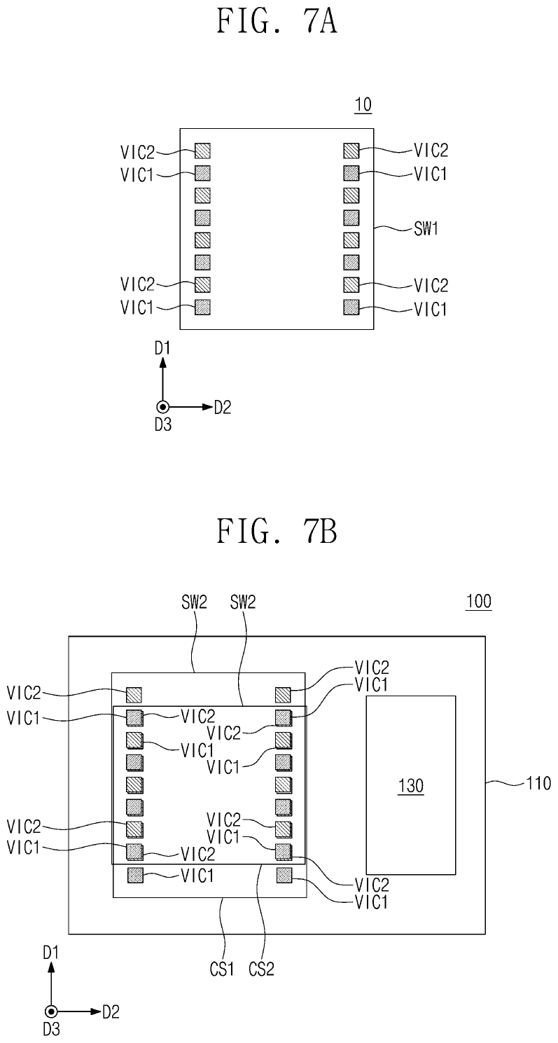

FIG. 7A illustrates a simplified plan view showing a semiconductor chip according to some embodiments of the present inventive concepts. FIG. 7B illustrates a simplified plan view showing a semiconductor package including the semiconductor chip depicted in FIG. 7A. The same technical features as those of the embodiments discussed above may be omitted in the interest of brevity of description.

Referring to FIG. 7A, each semiconductor chip 10 according to some embodiments of the present inventive concepts may include the first and second vertical connection structures VIC1 and VIC2 that are arranged adjacent to first sidewalls SW1 that are opposite to each other in the second direction D2. The first and second vertical connection structures VIC1 and VIC2 may be alternately arranged along the first direction D1. In addition, the first vertical connection structures VIC1 may be disposed spaced apart from each other in the second direction D2, and the second vertical connection structures VIC2 may be disposed spaced apart from each other in the second direction D2.

Referring to FIG. 7B, first and second chip stacks CS1 and CS2 may be stacked on the package substrate 110 to allow their second sidewalls SW2 that are spaced apart from each other in the first direction D1.

The first and second vertical connection structures VIC1 and VIC2 may be connected to each other on opposite sides of the first and second chip stacks CS1 and CS2. The first vertical connection structures VIC1 of the second chip stack CS2 may overlap and connect with the second vertical connection structures VIC2 of the first chip stack CS1. In some embodiments, the first chip stack CS1 may be between the package substrate 110 and the second chip stack CS2.

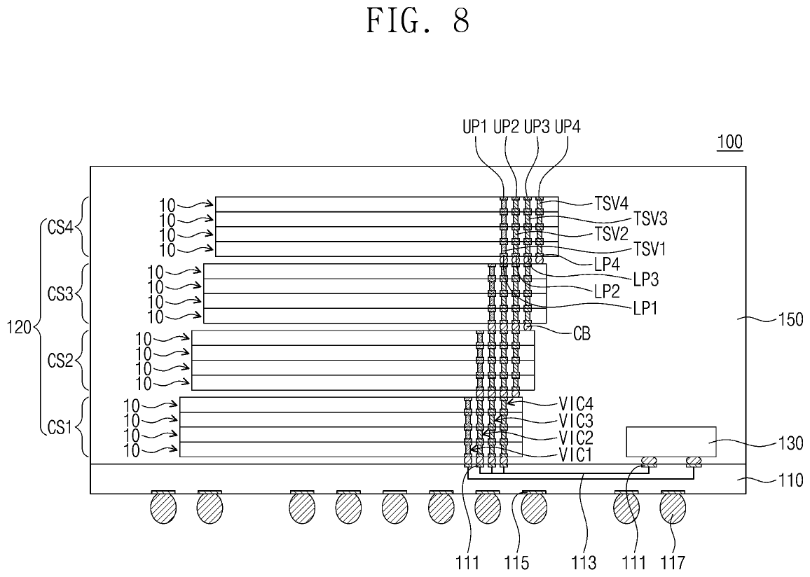

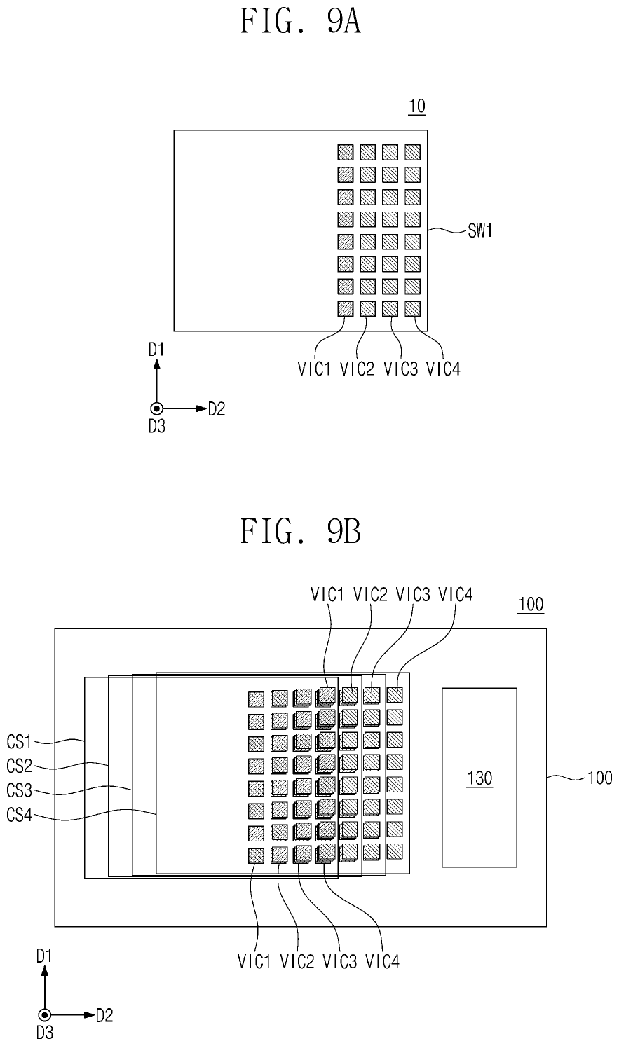

FIG. 8 illustrates a cross-sectional view showing a semiconductor package according to some example embodiments of the present inventive concepts. FIG. 9A illustrates a simplified plan view showing a semiconductor chip according to some embodiments of the present inventive concepts. FIG. 9B illustrates a simplified plan view showing a semiconductor package including the semiconductor chip depicted in FIG. 9A. The same technical features as those of the embodiments discussed above may be omitted in the interest of brevity of description.

Referring to FIG. 8, the semiconductor package 100 according to some embodiments of the present inventive concepts may include first, second, third, and fourth chip stacks CS1, CS2, CS3, and CS4 that are sequentially stacked on the package substrate 110. The first, second, third, and fourth chip stacks CS1, CS2, CS3, and CS4 may be stacked to allow their sidewalls to be spaced apart from each other in one direction (e.g., a horizontal direction).

Each of the first, second, third, and fourth chip stacks CS1, CS2, CS3, and CS4 may include a plurality of vertically stacked semiconductor chips 10. In each of the first, second, third, and fourth chip stacks CS1, CS2, CS3, and CS4, the semiconductor chips 10 may have their sidewalls that are vertically aligned with each other. The plurality of vertically stacked semiconductor chips 10 (also referred to as the plurality of semiconductor chips 10) may include a plurality of first semiconductor chips 10, a plurality of second semiconductor chips 10, a plurality of third semiconductor chips 10 and a plurality of fourth semiconductor chips 10, which are included in the first, second, third, and fourth chip stacks CS1, CS2, CS3, and CS4, respectively.

According to some embodiments, each of the semiconductor chips 10 may include first, second, third, and fourth vertical connection structures VIC1, VIC2, VIC3, and VIC4.

Referring to FIG. 9A, in each semiconductor chip 10, the first, second, third, and fourth vertical connection structures VIC1, VIC2, VIC3, and VIC4 may be sequentially disposed along a second direction D2. The first vertical connection structures VIC1 may be arranged at a regular interval along the first direction D1. The second vertical connection structures VIC2 may be disposed spaced part in the second direction D2 from the first vertical connection structures VIC1. The third vertical connection structures VIC3 may be disposed spaced apart in the second direction D2 from the second vertical connection structures VIC2, and the fourth vertical connection structures VIC4 may be disposed spaced apart in the second direction D2 from the third vertical connection structures VIC3. The fourth vertical connection structures VIC4 may be adjacent to the first sidewall SW1 than the first, second, and fourth vertical connection structures VIC1, VIC2, and VIC3.

Each of the first, second, third, and fourth vertical connection structures VIC1, VIC2, VIC3, and VIC4 may include upper pads UP1, UP2, UP3, and UP4, lower pads LP1, LP2, LP3, and LP4, and through vias TSV1, TSV2, TSV3, and TSV4 that connect the upper pads UP1, UP2, UP3, and UP4 to the lower pads LP1, LP2, LP3, and LP4. The first vertical connection structure VIC1 may be electrically connected to an internal circuit (e.g., conductive element) of a corresponding semiconductor chip 10, and each of the second, third, and fourth vertical connection structures VIC2, VIC3, and VIC4 may be insulated from an internal circuit of a corresponding semiconductor chip 10. Stated differently, the first vertical connection structure VIC1 of a single semiconductor chip 10 may be electrically connected to at least one of conductive elements (e.g., a source/drain region or a bit line) of that single semiconductor chip 10, and the second, third, and fourth vertical connection structures VIC2, VIC3, and VIC4 of a single semiconductor chip 10 may not be electrically connected to (i.e., may be electrically insulated from) any conductive element of that single semiconductor chip 10.

In each of the first, second, third, and fourth chip stacks CS1, CS2, CS3, and CS4, the first vertical connection structures VIC1 of the semiconductor chips 10 may be vertically aligned with each other and electrically connected to each other. This may hold true for the second, third, and fourth vertical connection structures VIC2, VIC3, and VIC4.

Connection bumps CB may be disposed between the first, second, third, and fourth chip stacks CS1, CS2, CS3, and CS4, and the connection bumps CB may electrically connect the first, second, third, and fourth chip stacks CS1, CS2, CS3, and CS4 to each other.

Referring to FIGS. 8 and 9B, in the semiconductor package 100 according to some embodiments of the present inventive concepts, a first sidewall SW1 of the second chip stack CS2 may be spaced apart in the second direction D2 from a first sidewall SW1 of the first chip stack CS1.

The first, second, and third vertical connection structures VIC1, VIC2, and VIC3 of the semiconductor chips 10 in the second chip stack CS2 may respectively overlap and connect with the second, third, and fourth vertical connection structures VIC2, VIC3, and VIC4 of the first chip stack CS1. The first vertical connection structures VIC1 of the second chip stack CS2 may be connected to a buffer chip 130 through the second vertical connection structures VIC2 of the first chip stack CS1. In the second chip stack CS2, the fourth vertical connection structure VIC4 may be electrically floated. For example, the fourth vertical connection structure VIC4 of the second chip stack CS2 may not be electrically connected to the first chip stack CS1.

The third chip stack CS3 may be stacked to allow its first sidewall SW1 to be spaced apart in the second direction D2 from the first sidewall SW1 of the second chip stack CS2.

The first, second, and third vertical connection structures VIC1, VIC2, and VIC3 of the semiconductor chips 10 in the third chip stack CS3 may respectively overlap and connect with the second, third, and fourth vertical connection structures VIC2, VIC3, and VIC4 of the second chip stack CS2. The first vertical connection structures VIC1 of the third chip stack CS3 may be connected to the buffer chip 130 through the second vertical connection structures VIC2 of the second chip stack CS2 and the third vertical connection structures VIC3 of the first chip stack CS1. In the third chip stack CS3, the third and fourth vertical connection structures VIC3 and VIC4 may be electrically floated. The third and fourth vertical connection structures VIC3 and VIC4 in the third chip stack CS3 may not be electrically connected to the first and second chip stacks CS1 and CS2.

The fourth chip stack CS4 may be stacked to allow its first sidewall SW1 to be spaced apart in the second direction D2 from the first sidewall SW1 of the third chip stack CS3.

The first, second, and third vertical connection structures VIC1, VIC2, and VIC3 of the semiconductor chips 10 in the fourth chip stack CS4 may respectively overlap and connect with the second, third, and fourth vertical connection structures VIC2, VIC3, and VIC4 of the third chip stack CS3. The first vertical connection structures VIC1 of the fourth chip stack CS4 may be connected to the buffer chip 130 through the second vertical connection structures VIC2 of the third chip stack CS3, the third vertical connection structures VIC3 of the second chip stack CS2, and the fourth vertical connection structures VIC4 of the first chip stack CS1. In the fourth chip stack CS4, the second, third, and fourth vertical connection structures VIC2, VIC3, and VIC4 may be electrically floated. The second, third, and fourth vertical connection structures VIC3 and VIC4 of the third chip stack CS3 may not be electrically connected to the first, second, and third chip stacks CS1, CS2, and CS3.

The buffer chip 130 may be mounted on the package substrate 110, and may be electrically connected through the package substrate 110 to the first, second, third, and fourth chip stacks CS1, CS2, CS3, and CS4.

FIG. 10A illustrates a cross-sectional view showing a semiconductor chip according to some embodiments of the present inventive concepts. FIG. 10B illustrates an enlarged view showing the section P3 of FIG. 10A.

Referring to FIGS. 10A and 10B, the semiconductor chip 10 according to some embodiments of the present inventive concepts may include a semiconductor substrate 200, a peripheral circuit structure PS on the semiconductor substrate 200, and a cell array structure CS on the peripheral circuit structure PS.

In some embodiments, the semiconductor substrate 200 may be, for example, a silicon substrate. The semiconductor substrate 200 may include a device region DR and a pad region PR.

A semiconductor device, or the semiconductor chip 10, according to some embodiments depicted in FIG. 10A may have a chip-to-chip (C2C) structure. The chip-to-chip (C2C) structure may be fabricated by forming on a first wafer (or the semiconductor substrate 200) an upper chip including the peripheral circuit structure PS, forming on a second wafer (or a semiconductor substrate other than the semiconductor substrate 200) a lower chip including the cell array structure CS, and then using a bonding method to connect the upper chip and the lower chip to each other. For example, the bonding method may mean a way of electrically connecting a bonding metal pad formed on an uppermost metal layer of the upper chip to a bonding metal pad formed on an uppermost metal layer of the lower chip. For example, when the bonding metal is formed of copper (Cu), the bonding method may be a Cu-to-Cu bonding method, and the bonding metal may be formed of aluminum (Al) or tungsten (W).

The peripheral circuit structure PS may include peripheral circuits PTR integrated on a front surface of the semiconductor substrate 200, peripheral circuit lines PLP connected to the peripheral circuits PTR, peripheral contact plugs PCP connected to the peripheral circuits PTR, and a peripheral circuit dielectric layer 210 that covers the peripheral circuits PTR, the peripheral circuit lines PLP, and the peripheral contact plugs PCP. A lower dielectric layer 205 may be provided on a rear surface of the semiconductor substrate 200.

The peripheral circuit structure PS may further include first bonding pads BP1 provided in the peripheral circuit dielectric layer 210. The first bonding pads BP1 may be electrically connected to the peripheral circuits PTR through the peripheral circuit lines PLP and the peripheral contact plugs PCP. The first bonding pads BP1 may have their top surfaces substantially coplanar with that of the peripheral circuit dielectric layer 210.

The cell array structure CS may be disposed on the peripheral circuit dielectric layer 210. According to some embodiments, the cell array structure CS may include three-dimensionally integrated memory cells and second bonding pads BP2 electrically connected to the memory cells.

According to some embodiments, memory cell strings (see the memory cell strings CSTR of FIG. 1) may be integrated on a semiconductor layer SL. A stack structure ST and first vertical structures VS1 may constitute the memory cell strings CSTR shown in FIG. 1. For example, the cell array structure CS may include a semiconductor layer SL, a stack structure ST, vertical structures VS, bit lines BL, and a cell array dielectric layer 310.

The stack structure ST may be disposed between the semiconductor layer SL and the peripheral circuit dielectric layer 210, and the bit lines BL may be disposed between the stack structure ST and the peripheral circuit dielectric layer 210.

The semiconductor layer SL may be formed of a semiconductor material, a dielectric material, or a conductive material. The semiconductor layer SL may include, for example, a semiconductor doped with impurities having a first conductivity type (e.g., n-type) and/or an intrinsic semiconductor doped with no impurities. In some embodiments, semiconductor layer SL may include at least one selected from a monocrystalline structure, an amorphous structure, and a polycrystalline structure. As used herein, the term “and/or” includes any and all combinations of one or more of the associated listed items.

The stack structure ST may include conductive patterns GE vertically stacked on a top surface (or a front surface) of the semiconductor layer SL. The conductive patterns GE may include, for example, at least one selected from doped semiconductors (e.g., doped silicon), metals (e.g., tungsten, copper, or aluminum), conductive metal nitrides (e.g., titanium nitride or tantalum nitride), and transition metals (e.g., titanium or tantalum).

According to some embodiments, a semiconductor device, or the semiconductor chip 10, may be a Flash memory device, and in this case, the conductive patterns GE of the stack structure ST may be used as the gate lower lines LL1 and LL2, the word lines WL, and the gate upper lines UL1 and UL2 discussed with reference to FIG. 1.

The conductive patterns GE may be stacked on the semiconductor layer SL to allow their ends to have a stepwise structure. The conductive patterns GE may have their lengths in one direction that increase with increasing from the peripheral circuit structure PS. The ends of the conductive patterns GE may be located at their positions horizontally and vertically different from each other.

A plurality of vertical structures VS may penetrate the stack structure ST. Although not shown, the device region DR may include dummy vertical structures having the same structure as that of the vertical structures VS, and the dummy vertical structure may penetrate the ends of the conductive patterns GE.

Each of the vertical structures VS may include a vertical semiconductor pattern and a data storage pattern that surrounds a sidewall of the vertical semiconductor pattern. The vertical semiconductor pattern may include a semiconductor material, such as silicon (Si), germanium (Ge), or a mixture thereof. The vertical semiconductor pattern including the semiconductor material may be used as channels of the upper transistors UT1 and UT2, the memory cell transistors MCT, and the lower transistors LT1 and LT2, all of which transistors are discussed with reference to FIG. 1. In some embodiments of the present inventive concepts, the data storage pattern may include a tunnel dielectric layer, a charge storage layer, and a blocking dielectric layer that are used as a data storage layer of a NAND Flash memory device. For example, the charge storage layer may be a trap dielectric layer, a floating gate electrode, or a dielectric layer including conductive nano-dots.

The cell array structure CS may include second bonding pads BP2 electrically connected to the bit lines BL and the conductive patterns GE (or word lines). The second bonding pads BP2 may be provided in an uppermost interlayer dielectric layer.

The second bonding pads BP2 may be electrically connected to the bit lines BL. A bonding method may be used to electrically and physically connect the second bonding pads BP2 to the first bonding pads BP1 of the peripheral circuit structure PS. For example, the second bonding pads BP2 may be in direct contact with the first bonding pads BP1.

The second bonding pads BP2 may include the same metallic material as that of the first bonding pads BP1. The first and second bonding pads BP1 and BP2 may be formed of, for example, aluminum, copper, or tungsten. The second bonding pads BP2 may have substantially the same arrangement, shape, width, and/or area as those of the first bonding pads BP1.

According to some embodiments, on the pad region PR, the semiconductor chip 10 may include first and second vertical connection structures that are discussed above. The first vertical connection structures may be provided closer to the device region DR than the second vertical connection structures, and may be electrically connected to the peripheral circuits PTR of the peripheral circuit structure PS.

For example, the first vertical connection structures may include a first lower pad LP1 provided in the lower dielectric layer 205 that covers a bottom surface (or a rear surface) of the semiconductor substrate 200, a first upper pad UP1 provided in an upper dielectric layer 305 that covers a bottom surface (or a rear surface) of the semiconductor layer SL, and a first through via TSV1 that connects the first lower pad LP1 to the first upper pad UP1.

The second vertical connection structures may include a second lower pad LP2 provided in the lower dielectric layer 205, a second upper pad UP2 provided in the upper dielectric layer 305, and a second through via TSV2 that connects the second lower pad LP2 to the second upper pad UP2.

Referring to FIG. 10B, each of the first and second through vias TSV1 and TSV2 may include a lower via TSVa provided in the peripheral circuit structure PS and an upper via TSVb provided in the cell array structure CS. The lower via TSVa may penetrate the semiconductor substrate 200. The lower via TSVa may be connected to the first bonding pad BP1 through conductive lines and contact plugs, and the upper via TSVa may be connected to the second bonding pad BP2 through conductive lines and contact plugs. The first bonding pad BP1 and the second bonding pad BP2 may be directly bonded to each other. The first through via TSV1 may be electrically connected to the peripheral circuit lines PLP to the peripheral circuits PTR. The second through via TSV2 may be insulated from the peripheral circuits PTR and a cell array.

FIG. 11 illustrates a cross-sectional view showing a semiconductor chip according to some embodiments of the present inventive concepts. The same technical features as those of the embodiments discussed above with reference to FIGS. 10A and 10B will be omitted in the interest of brevity of description.

Referring to FIG. 11, a semiconductor chip 10 according to some embodiments of the present inventive concepts may include a semiconductor substrate 200, a peripheral circuit structure PS on the semiconductor substrate 200, and a cell array structure CS on the peripheral circuit structure PS.

The peripheral circuit structure PS may include peripheral circuits PTR integrated on a front surface of the semiconductor substrate 200, peripheral circuit lines PLP connected to the peripheral circuits PTR, peripheral contact plugs PCP connected to the peripheral circuits PTR, and a peripheral circuit dielectric layer 210.

The semiconductor layer SL may be disposed on a top surface of the peripheral circuit dielectric layer 210.

A stack structure ST may include conductive patterns GE vertically stacked on the semiconductor layer SL, and the conductive patterns GE may have their lengths in one direction that increase with increasing distance from the peripheral circuit structure PS. The conductive patterns GE may be stacked on the semiconductor layer SL to allow their ends to have a stepwise structure.

A plurality of vertical structures VS may penetrate the stack structure ST. As discussed above, the vertical structures VS may include a vertical semiconductor pattern and a data storage pattern that surrounds the vertical semiconductor pattern.

A plurality of through structures THV may penetrate the stack structure ST, and each through structure THV may include a conductive plug that connects the cell array structure CS to the peripheral circuit structure PS and a vertical dielectric layer that surrounds the conductive plug.

According to some embodiments, on the pad region PR, the semiconductor chip 10 may include first and second vertical connection structures that are discussed above. The first vertical connection structure may include a first upper pad UP1, a first through via TSV1, and a first lower pad LP1, and the second vertical connection structure may include a second upper pad UP2, a second through via TSV2, and a second lower pad LP2.

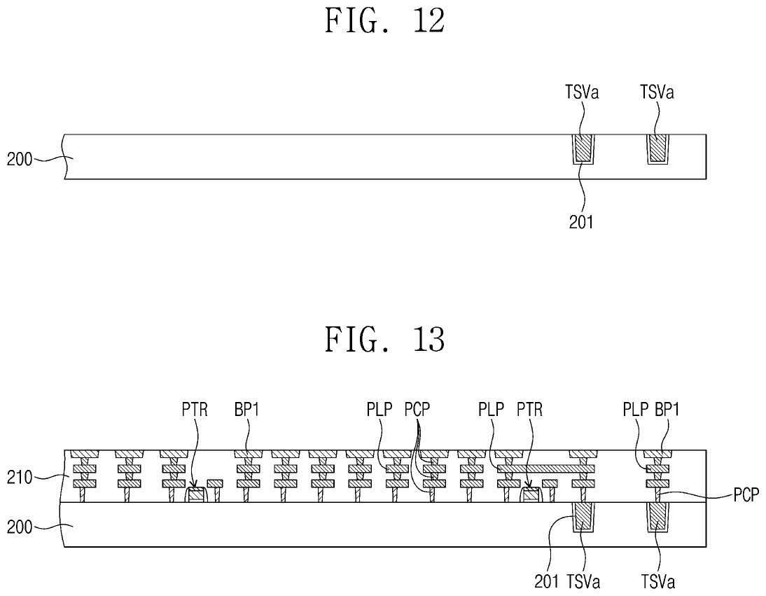

FIGS. 12 to 20 illustrate cross-sectional views showing a method of fabricating a semiconductor chip according to some embodiments of the present inventive concepts.

Referring to FIG. 12, lower vias TSVa may be formed in a semiconductor substrate 200 (referred to hereinafter as a first semiconductor substrate). A dielectric spacer 201 may be formed between each of the lower vias TSVa and the first semiconductor substrate 200.

The first semiconductor substrate 200 may include, for example, at least one selected from silicon (Si), germanium (Ge), silicon germanium (SiGe), gallium arsenic (GaAs), indium gallium arsenic (InGaAs), aluminum gallium arsenic (AlGaAs), and a mixture thereof.

The formation of the lower vias TSVa and the dielectric spacers 201 may include patterning a portion of the first semiconductor substrate 200 to form openings, forming a dielectric layer that conformally covers the openings, forming a conductive layer that fills the openings in which the dielectric layer is formed, and performing on the conductive layer and the dielectric layer a planarization process to expose a top surface of the first semiconductor substrate 200.

The lower vias TSVa may be formed of, for example, metal, such as aluminum or tungsten. The dielectric spacer 201 may be formed of, for example, an oxide layer, a nitride layer, or a combination thereof.

Referring to FIG. 13, a peripheral circuit structure PS may be formed which includes peripheral circuits PTR formed on the first semiconductor substrate 200.

For example, the formation of the peripheral circuit structure PS may include forming the peripheral circuits PTR on an active area on the first semiconductor substrate 200, forming peripheral contact plugs PCP, peripheral circuit lines PLP, and first bonding pads BP1 that are electrically connected to the peripheral circuits PTR, and forming a peripheral circuit dielectric layer 210 that covers the peripheral contact plugs PCP, the peripheral circuit lines PLP, and the first bonding pads BP1. The peripheral circuit dielectric layer 210 may have a single-layered structure or a multi-layered structure.

Row and column decoders, page buffers, and control circuits may be formed as the peripheral circuits PTR on the first semiconductor substrate 200. The peripheral circuits PTR may include metal oxide semiconductor (MOS) transistors each of which uses the first semiconductor substrate 200 as a channel.

The peripheral circuit dielectric layer 210 may include one or a plurality of stacked dielectric layers that cover the peripheral circuits PTR. The peripheral circuit dielectric layer 210 may include, for example, one or more of a silicon oxide layer, a silicon nitride layer, a silicon oxynitride layer, and a low-k dielectric layer.

The peripheral contact plugs PCP may be formed to penetrate a portion of the peripheral circuit dielectric layer 210 and to connect the peripheral circuits PTR to the peripheral circuit lines PLP. The peripheral circuit lines PLP may be formed by depositing a conductive layer and patterning the conductive layer.

The first bonding pads BP1 may be formed in an uppermost peripheral circuit dielectric layer 210, or an uppermost one of the multi-layered peripheral circuit dielectric layer 210. The first bonding pads BP1 may be electrically connected to the peripheral circuits PTR through the peripheral contact plugs PCP and the peripheral circuit lines PLP. In addition, the first bonding pads BP1 may be electrically connected to the lower vias TSVa through the peripheral contact plugs PCP and the peripheral circuit lines PLP.

In some embodiments, a damascene process may be used to form the first bonding pads BP1. The first bonding pads BP1 may have their top surfaces substantially coplanar with that of the peripheral circuit dielectric layer 210. In this description below, the phrase “substantially coplanar with” may mean that a planarization process can be performed. The planarization process may include, for example, a chemical mechanical polishing (CMP) process or an etch-back process.

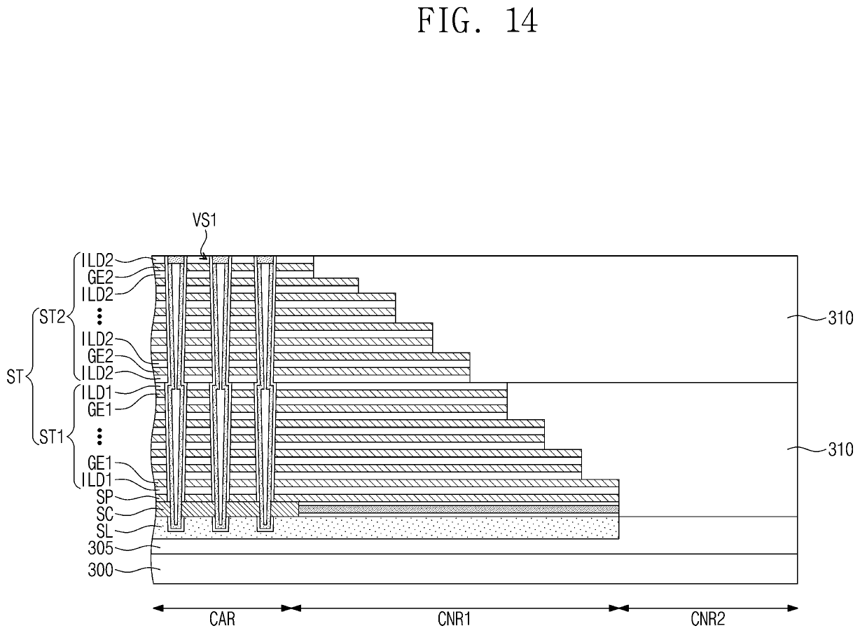

Referring to FIG. 14, a stack structure ST and first vertical structures VS1 may be formed on a second semiconductor substrate 300.

For example, an upper dielectric layer 305 and a semiconductor layer SL may be formed on the second semiconductor substrate 300.

The second semiconductor substrate 300 may include a cell array region CAR, a first connection region CNR1, and a second connection region CNR2, and the first connection region CNR1 may be positioned in a first direction D1 between the cell array region CAR and the second connection region CNR2.

A deposition method may be used to form the upper dielectric layer 305 and the semiconductor layer SL. The semiconductor layer SL may include an impurity-doped semiconductor and/or an impurity-undoped intrinsic semiconductor. For example, the semiconductor layer SL may be formed by depositing a polysilicon layer.

The formation of the stack structure ST may include forming on the semiconductor layer SL a mold structure (not shown) including vertically stacked sacrificial layers (not shown), and replacing the sacrificial layers of the mold structure with conductive patterns GE1 and GE2. The replacement of the conductive patterns GE1 and GE2 may be performed after the formation of the first vertical structures VS1.

The stack structure ST may include a first stack structure ST1 and a second stack structure ST2 on the first stack structure ST1. The first stack structure ST1 may include first interlayer dielectric layers ILD1 and first conductive patterns GE1 that are alternately stacked, and the second stack structure ST2 may include second interlayer dielectric layers ILD2 and second conductive patterns GE2 that are alternately stacked.

The first and second conductive patterns GE1 and GE2 of the stack structure ST may be stacked to have a stepwise structure on the first connection region CNR1. For example, the first and second conductive patterns GE1 and GE2 may have their lengths in the first direction D1 that decrease with increasing distance from the second semiconductor substrate 300.

A cell array dielectric layer 310 may be formed to cover the stepwise structure of the first and second stack structures ST1 and ST2.

The first and second conductive patterns GE1 and GE2 may include, for example, at least one selected from doped semiconductors (e.g., doped silicon), metals (e.g., tungsten, molybdenum, nickel, copper, or aluminum), conductive metal nitrides (e.g., titanium nitride or tantalum nitride), and transition metals (e.g., titanium or tantalum). The first and second interlayer dielectric layers ILD1 and ILD2 may include one or more of silicon oxide, silicon nitride, silicon oxynitride, and low-k dielectrics. For example, the first and second interlayer dielectric layers ILD1 and ILD2 may include high-density plasma (HDP) oxide or tetraethylorthosilicate (TEOS).

Before the formation of the first and second conductive patterns GE1 and GE2, the formation of the first vertical structures VS1 may include forming vertical holes to penetrate the mold structure (not shown) and forming a data storage layer and a vertical semiconductor pattern in the vertical holes.

According to some embodiments, before the stack structure ST is formed on the semiconductor layer SL, a source semiconductor pattern SC and a support semiconductor layer SP may be formed between the semiconductor layer SL and the stack structure ST.

The source semiconductor pattern SC may be formed of a semiconductor material doped with impurities (e.g., phosphorus (P) or arsenic (As)) having a first conductivity type. For example, the source semiconductor pattern SC may be formed of a polysilicon layer doped with n-type impurities.

The support semiconductor layer SP may cover a top surface of the source semiconductor pattern SC, and may include a semiconductor doped with impurities having the first conductivity type (e.g., n-type) and/or an intrinsic semiconductor doped with no impurities. A concentration of n-type impurities may be less in the support semiconductor layer SP than in the source semiconductor pattern SC.

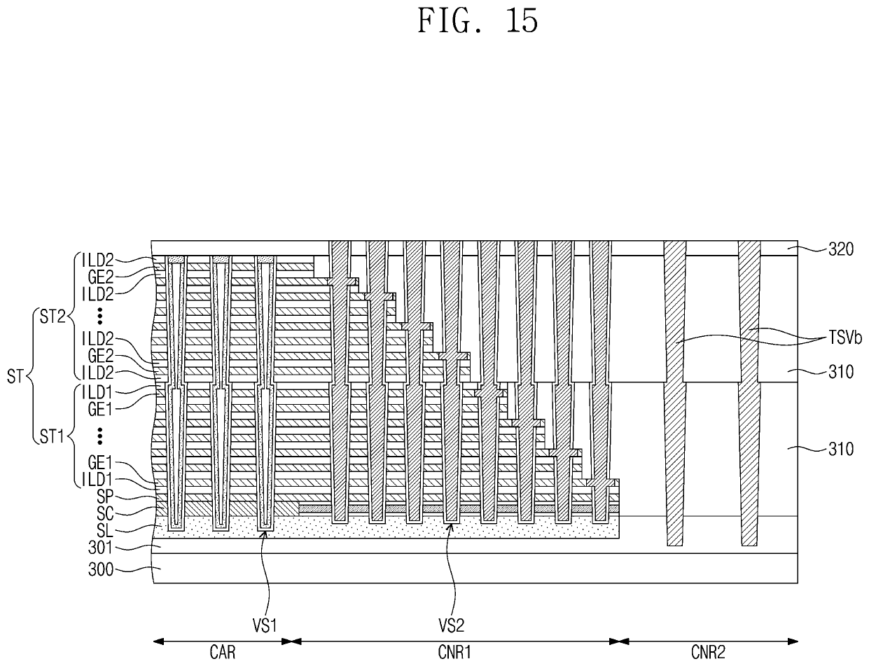

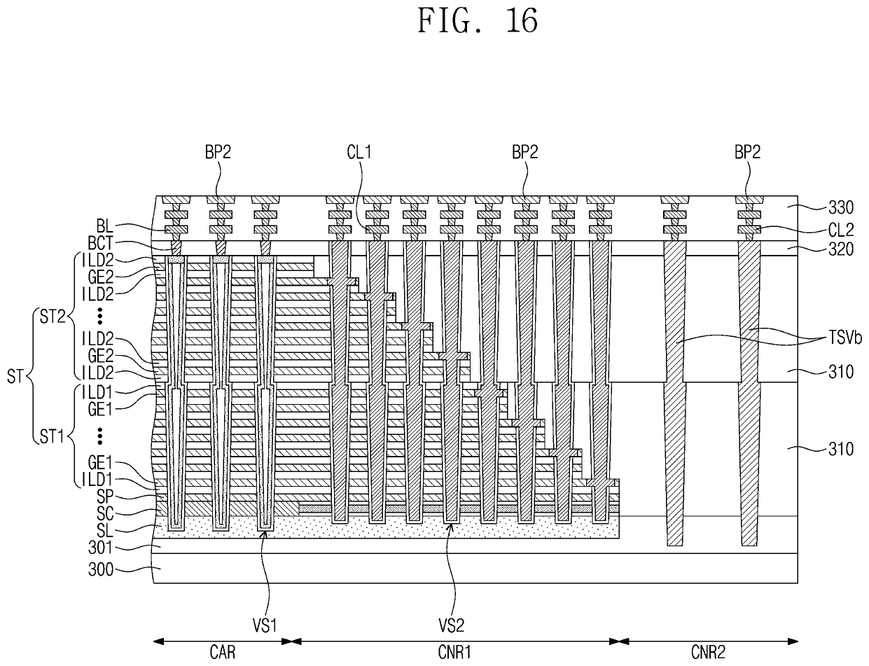

Referring to FIG. 15, an interlayer dielectric layer 320 may be formed to cover the stack structure ST and the cell array dielectric layer 310. Second vertical structures VS2 may be formed on the first connection region CNR1.

On the first connection region CNR1, the second vertical structures VS2 may penetrate ends of the first and second conductive patterns GE1 and GE2. For example, each of the second vertical structures VS2 may include a conductive plug and a dielectric pattern between the conductive plug and each of the first and second conductive patterns GE1 and GE2. The conductive plug of each second vertical structure VS2 may include a portion in contact with one of the first and second conductive patterns GE1 and GE2. In some embodiments, the second vertical structures VS2 may have the same structure and material as those of the first vertical structures VS1.

On the second connection region CNR2, upper vias TSVb may be formed to penetrate the cell array dielectric layer 310.

The upper vias TSVb may be formed by forming through holes that penetrate the interlayer dielectric layer 320 and the cell array dielectric layer 310 and expose the upper dielectric layer 305, and then filling the through holes with a conductive material.

Referring to FIG. 16, bit-line contact plugs BCT may be formed on the cell array region CAR, and contact plugs may be formed on the first and second connection regions CNR1 and CNR2.

The bit-line contact plugs BCT may be connected to the first vertical structures VS1. The contact plugs may be connected to the second vertical structures VS2 and the upper vias TSVb.

Bit lines BL and first and second conductive lines CL1 and CL2 may be formed in an interlayer dielectric layer 330. The interlayer dielectric layer 330 may have a single-layered structure or a multi-layered structure.

The bit lines BL may be connected to the bit-line contact plugs BCT, and on the first connection region CNR1, the first conductive lines CL1 may be connected through the contact plugs to the second vertical structures VS2. On the second connection region CNR2, the second conductive lines CL2 may be connected through the contact plugs to the upper vias TSVb.

Second bonding pads BP2 may be formed in an uppermost interlayer dielectric layer 330, and the second bonding pads BP2 may be connected to the first and second conductive lines CL1 and CL2.

In some embodiments, a damascene process may be used to form the second bonding pads BP2. The second bonding pads BP2 may have their top surfaces substantially coplanar with that of the uppermost interlayer dielectric layer 330.

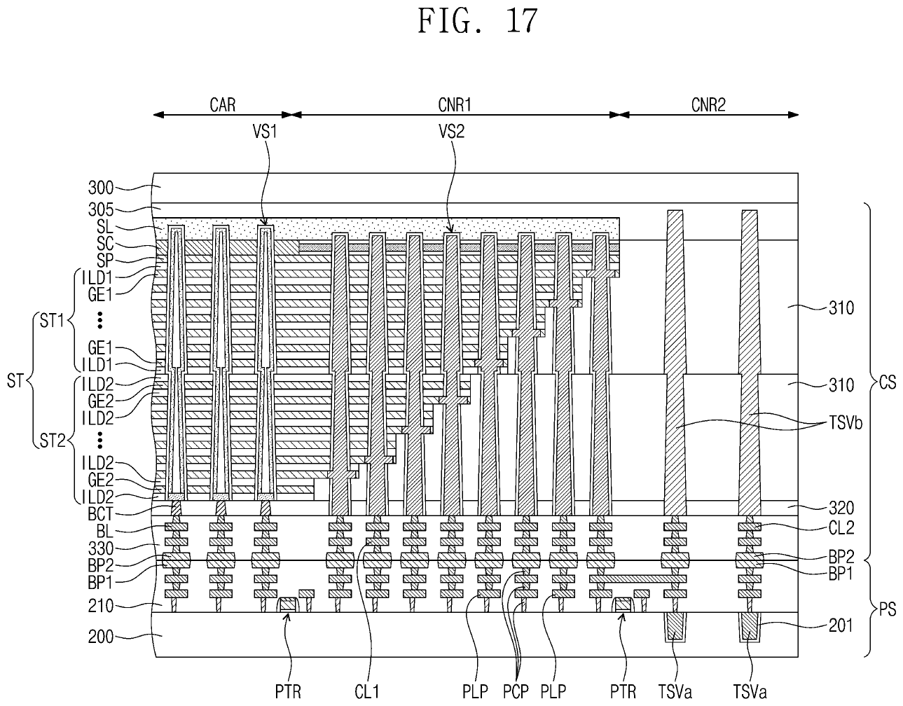

Referring to FIG. 17, the cell array structure CS formed on the second semiconductor substrate 300 may be bonded to the peripheral circuit structure PS formed on the first semiconductor substrate 200.

For example, the first bonding pads BP1 of the peripheral circuit structure PS may be bonded to the second bonding pads BP2 of the cell array structure CS. Therefore, the first bonding pads BP1 and the second bonding pads BP2 may be bonded to each other, and the uppermost peripheral circuit dielectric layer 210 of the first semiconductor substrate 200 may be bonded to the uppermost interlayer dielectric layer 330 of the second semiconductor substrate 300.

As the first and second bonding pads BP1 and BP2 are bonded to each other, the cell array structure CS may be turned upside down. For example, the second semiconductor substrate 300 of the cell array structure CS may be located at an uppermost position, and the stepwise structure of the stack structure ST may be disposed in an inverse position.

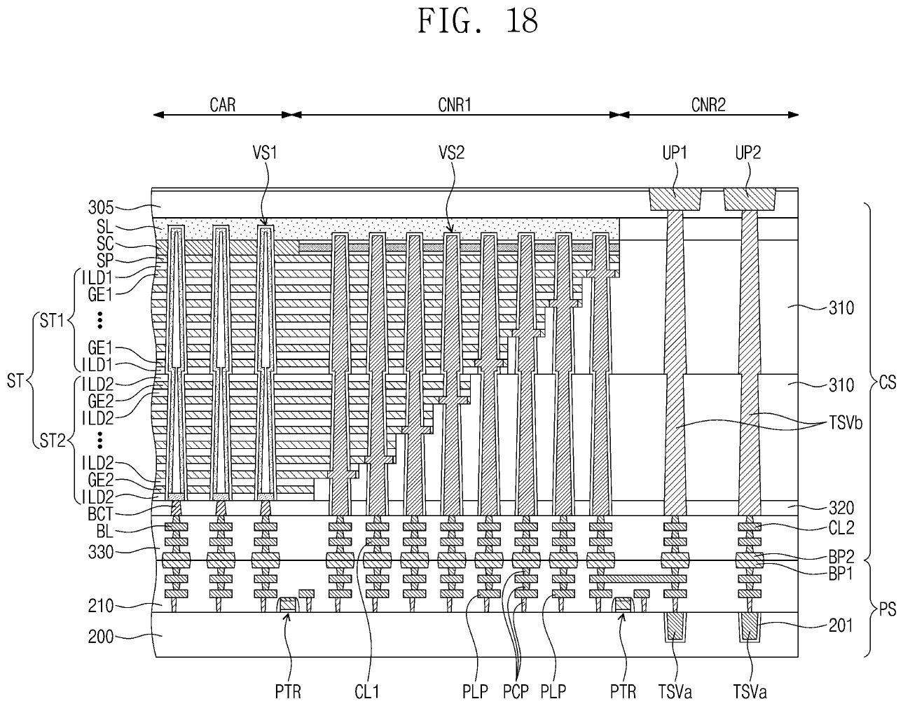

Referring to FIG. 18, after the bonding between the first bonding pads BP1 and the second bonding pads BP2, the second semiconductor substrate 300 may be removed. The second semiconductor substrate 300 may be removed by, for example, a grinding process, a planarization process, a dry etching process, and/or a wet etching process. The removal of the second semiconductor substrate 300 may expose the upper dielectric layer 305.

First and second upper pads UP1 and UP2 may be formed in the upper dielectric layer 305. The first and second upper pads UP1 and UP2 may be formed by patterning the upper dielectric layer 305 to form openings that correspondingly expose the upper vias TSVb, and then filling the openings with a conductive material.

The first and second upper pads UP1 and UP2 may be electrically connected through the upper vias TSVb to the second bonding pads BP2.

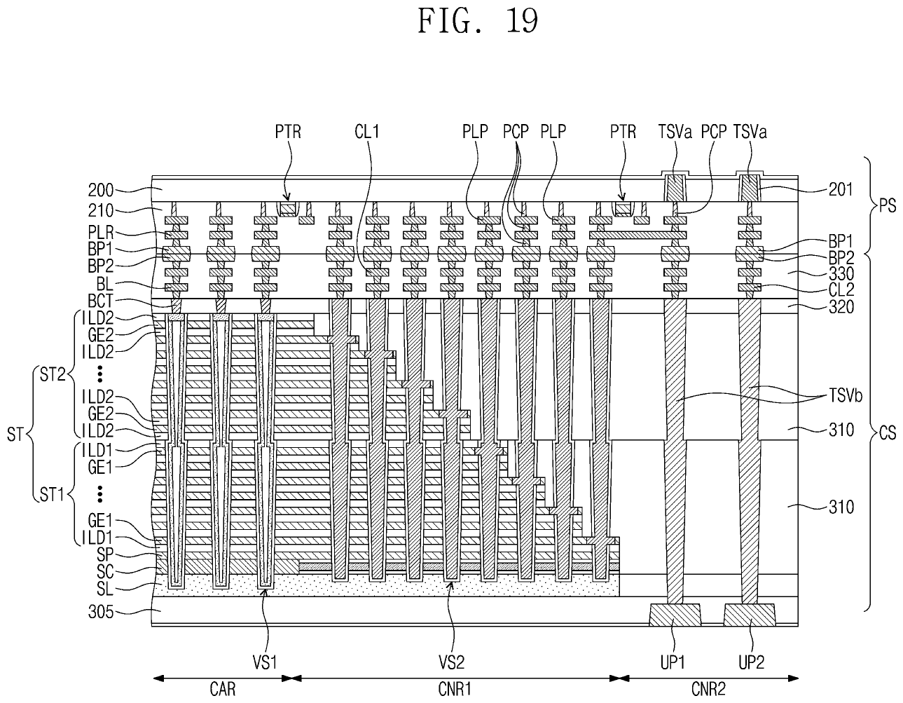

Referring to FIG. 19, after the formation of the first and second upper pads UP1 and UP2, the cell array structure CS and the peripheral circuit structure PS may be turned upside down. Thus, the first semiconductor substrate 200 may be located at an uppermost position.

A rear surface of the first semiconductor substrate 200 may undergo a grinding process and a planarization process to expose the lower vias TSVa.

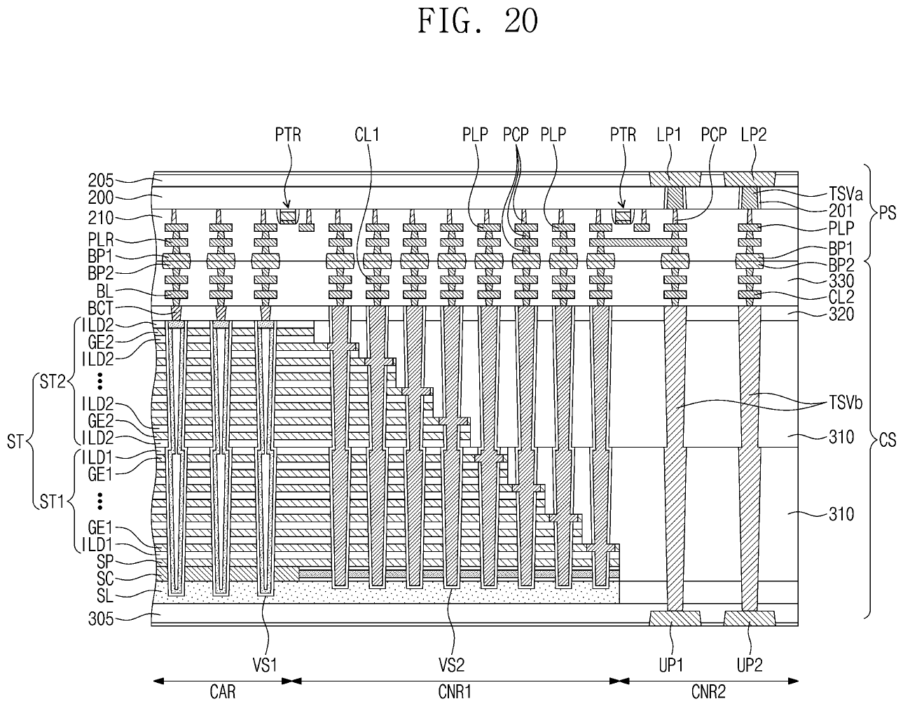

Referring to FIG. 20, after the exposure of the lower vias TSVa, a lower dielectric layer 205 may be formed to cover a rear surface of the first semiconductor substrate 200.

First and second lower pads LP1 and LP2 may be formed in the lower dielectric layer 205. The first and second lower pads LP1 and LP2 may be formed by patterning the lower dielectric layer 205 to form openings that correspondingly expose the lower vias TSVa, and then filling the openings with a conductive material.

The first and second lower pads LP1 and LP2 may be electrically connected through the lower vias TSVa to the first bonding pads BP1. For example, the first lower pad LP1 may be electrically connected to the first upper pad UP1, and the second lower pad LP2 may be electrically connected to the second upper pad UP2.

According to some embodiments of the present inventive concepts, in a semiconductor package including a lower chip stack and an upper chip stack, the upper chip stack may be connected, without bonding wires, to a buffer chip though vertical connection structures in the lower chip stack. It may thus be possible to reduce a signal delay between the buffer chip and the upper chip stack.

Accordingly, a semiconductor package and a semiconductor device may improve in operating characteristics.

Although terms (e.g., first, second or third) may be used herein to describe various elements, these elements should not be limited by these terms. These terms are only used to distinguish one element from another. For example, a first element may be referred to as a second element, and, similarly a second element may be referred to as a first element without departing from the teachings of the disclosure.

As used herein, “an element A connected to an element B” (or similar language) may mean that the element A is electrically connected to the element B and/or the element A contacts the element B.

It is noted that aspects of the invention described with respect to one embodiment, may be incorporated in a different embodiment although not specifically described relative thereto. That is, all embodiments and/or features of any embodiment can be combined in any way and/or combination.

Although the present inventive concepts have been described in connection with some embodiments of the present inventive concepts illustrated in the accompanying drawings, it will be understood to those skilled in the art that various changes and modifications may be made without departing from the scope and essential feature of the present inventive concepts. It will be apparent to those skilled in the art that various substitution, modifications, and changes may be thereto without departing from the scope of the present inventive concepts.

What is claimed is:

1. A semiconductor package comprising:
a package substrate; and
a first chip stack and a second chip stack that are stacked on the package substrate,
wherein the first chip stack includes a plurality of first semiconductor chips, the second chip stack include a plurality of second semiconductor chips, the plurality of first semiconductor chips are stacked vertically, and the plurality of second semiconductor chips are stacked vertically,
wherein each of the plurality of first semiconductor chips and the plurality of second semiconductor chips includes a plurality of first vertical connection structures and a plurality of second vertical connection structures, and
wherein the plurality of first vertical connection structures of the plurality of second semiconductor chips overlap and are electrically connected with the plurality of second vertical connection structures of the plurality of first semiconductor chips, respectively.

2. The semiconductor package of claim 1, further comprising a buffer chip on the package substrate,
wherein the plurality of second vertical connection structures of the plurality of first semiconductor chips electrically connect the buffer chip to the plurality of first vertical connection structures of the plurality of second semiconductor chips.

3. The semiconductor package of claim 1, wherein, in each of the plurality of first semiconductor chips and the plurality of second semiconductor chips, the plurality of first vertical connection structures are electrically connected to an internal circuit of each of the plurality of first semiconductor chips and the plurality of second semiconductor chips, and the plurality of second vertical connection structures are electrically insulated from the internal circuit.

4. The semiconductor package of claim 1, wherein
in each of the plurality of first semiconductor chips and the plurality of second semiconductor chips, the plurality of first vertical connection structures are arranged along a first direction, and the plurality of second vertical connection structures are spaced apart in a second direction from the plurality of first vertical connection structures,
a sidewall of the first chip stack is spaced apart in the second direction from a sidewall of the second chip stack, and
the sidewalls of the first and second chip stacks are parallel to the first direction.

5. The semiconductor package of claim 1, wherein
in each of the plurality of first semiconductor chips and the plurality of second semiconductor chips, the plurality of first vertical connection structures and the plurality of second vertical connection structures are alternately arranged along a first direction,
a sidewall of the first chip stack is spaced apart in the first direction from a sidewall of the second chip stack, and
the sidewalls of the first and second chip stacks are parallel to a second direction that intersects the first direction.

6. The semiconductor package of claim 1, wherein
sidewalls of the plurality of first semiconductor chips are vertically aligned with each other, and sidewalls of the plurality of second semiconductor chips are vertically aligned with each other, and
the sidewalls of the plurality of first semiconductor chips are misaligned with the sidewalls of the plurality of second semiconductor chips.

7. The semiconductor package of claim 1, wherein the plurality of second vertical connection structures of the plurality of second semiconductor chips are electrically floated.

8. The semiconductor package of claim 1, wherein
each of the plurality of first vertical connection structures includes a first upper pad, a first lower pad, and a first through via that electrically connects the first upper pad to and the first lower pad, and
each of the plurality of second vertical connection structures includes a second upper pad, a second lower pad, and a second through via that electrically connects the second upper pad to the second lower pad.

9. The semiconductor package of claim 1, further comprising a plurality of connection bumps between the first chip stack and the second chip stack,
wherein the plurality of connection bumps are between the plurality of first vertical connection structures of a lowermost one of the plurality of second semiconductor chips and the plurality of second vertical connection structures of an uppermost one of the plurality of first semiconductor chips.

10. The semiconductor package of claim 1, wherein each of the plurality of first semiconductor chips and the plurality of second semiconductor chips includes:
a semiconductor substrate;
a peripheral circuit structure that includes peripheral circuits on the semiconductor substrate and first bonding pads electrically connected to the peripheral circuits; and
a cell array structure that includes second bonding pads contacting the first bonding pads, wherein the cell array structure includes three-dimensionally integrated memory cells,
wherein the plurality of first vertical connection structures are electrically connected to the peripheral circuits, and
wherein the plurality of second vertical connection structures are electrically insulated from the peripheral circuits.

11. The semiconductor package of claim 1, further comprising:
a third chip stack on the second chip stack; and
a fourth chip stack on the third chip stack,
wherein the third chip stack includes a plurality of third semiconductor chips and the fourth chip stack includes a plurality of fourth semiconductor chips, the plurality of third semiconductor chips are stacked vertically, and the plurality of fourth semiconductor chips are stacked vertically,
wherein each of the plurality of third semiconductor chips and the plurality of fourth semiconductor chips includes a plurality of first vertical connection structures and a plurality of second vertical connection structures,
wherein each of the plurality of first semiconductor chips, the plurality of second semiconductor chips, the plurality of third semiconductor chips, and the plurality of fourth semiconductor chips further includes a plurality of third vertical connection structures and a plurality of fourth vertical connection structures,
wherein the plurality of first vertical connection structures of the plurality of third semiconductor chips overlap and are electrically connected with the plurality of second vertical connection structures of the plurality of second semiconductor chips, respectively, and
wherein the plurality of second vertical connection structures of the plurality of second semiconductor chips overlap and are electrically connected with the plurality of third vertical connection structures of the plurality of first semiconductor chips, respectively.

12. The semiconductor package of claim 11, wherein the plurality of first vertical connection structures of the plurality of fourth semiconductor chips, respectively, overlap and are electrically connected with the plurality of second vertical connection structures of the plurality of third semiconductor chips, respectively, the plurality of third vertical connection structures of the plurality of second semiconductor chips, and the plurality of fourth vertical connection structures of the plurality of first semiconductor chips.

13. A semiconductor device comprising:
a semiconductor substrate;
a peripheral circuit structure that includes peripheral circuits on the semiconductor substrate and first bonding pads electrically connected to the peripheral circuits;
a cell array structure that includes second bonding pads contacting the first bonding pads, wherein the cell array structure includes three-dimensionally integrated memory cells;
a plurality of first vertical connection structures electrically connected to the peripheral circuits, wherein each of the plurality of first vertical connection structures includes a first upper pad, a first lower pad, and a first through via that is between the first upper pad and the first lower pad and electrically connects the first upper pad to the first lower pad; and
a plurality of second vertical connection structures electrically insulated from the peripheral circuits, wherein each of the plurality of second vertical connection structures includes a second upper pad, a second lower pad, and a second through via that is between the second upper pad to the second lower pad electrically connects the second upper pad to the second lower pad,
wherein the first and second upper pads are on an uppermost surface of the cell array structure, and
wherein the first and second lower pads are on a lowermost surface of the peripheral circuit structure.

14. The semiconductor device of claim 13, wherein each of the first and second through vias includes:
an upper via in the cell array structure; and
a lower via in the peripheral circuit structure,
wherein the lower via is electrically connected to at least one of the first bonding pads, and
wherein the upper via is electrically connected to at least one of the second bonding pads.

15. The semiconductor device of claim 13, wherein
the semiconductor substrate includes a device region and a pad region,
the peripheral circuits and the memory cells are on the device region,
the plurality of first vertical connection structures and the plurality of second vertical connection structures are on the pad region, and
the plurality of first vertical connection structures are closer to the device region than the plurality of second vertical connection structures.

16. The semiconductor device of claim 13, wherein the first through via is electrically connected through conductive lines to the peripheral circuits.

17. The semiconductor device of claim 13, wherein the cell array structure further includes:
a stack structure that includes a plurality of vertically stacked conductive patterns;
a plurality of vertical structures, each of which is in the stack structure and includes a data storage layer; and
a plurality of bit lines that traverse the stack structure and are electrically connected to the plurality of vertical structures.

18. A semiconductor package comprising:
a package substrate;
a first chip stack on the package substrate;
a second chip stack on the first chip stack; and
a buffer chip on the package substrate,
wherein the first chip stack includes a plurality of first semiconductor chips, the second chip stack includes a plurality of second semiconductor chips, the plurality of first semiconductor chips are vertically stacked, and the plurality of second semiconductor chips are vertically stacked,
wherein each of the plurality of first semiconductor chips and the plurality of second semiconductor chips includes:
a semiconductor substrate;
a peripheral circuit structure that includes peripheral circuits on the semiconductor substrate and first bonding pads electrically connected to the peripheral circuits;
a cell array structure that includes second bonding pad contacting the first bonding pads, wherein the cell array structure includes three-dimensionally integrated memory cells;
a plurality of first vertical connection structures electrically connected to the peripheral circuits; and
a plurality of second vertical connection structures electrically insulated from the peripheral circuits,
wherein the plurality of first vertical connection structures of the plurality of second semiconductor chips overlap and are electrically connected with the plurality of second vertical connection structures of the plurality of first semiconductor chips, and
wherein the plurality of first vertical connection structures of the second chip stack are electrically connected to the buffer chip through the plurality of second vertical connection structures of the first chip stack.

19. The semiconductor package of claim 18, wherein the plurality of second vertical connection structures of the plurality of second semiconductor chips are electrically floated.

20. The semiconductor package of claim 18, wherein
sidewalls of the plurality of first semiconductor chips are vertically aligned with each other, and sidewalls of the plurality of second semiconductor chips are vertically aligned with each other, and
the sidewalls of the plurality of first semiconductor chips are misaligned with the sidewalls of the plurality of second semiconductor chips.
